(19) United States
(12) Patent Application Publication
(10) Pub. No.: US 2022/0151113 A1
(43) Pub. Date: May 12, 2022

(54) ELECTRONIC DEVICE

(71) Applicant: NEC Corporation, Minato-ku, Tokyo (JP)

(72) Inventors: Mahiro HACHIYA, Tokyo (JP); Minoru YOSHIKAWA, Tokyo (JP); Takashi OHTSUKA, Tokyo (JP); Nobuo KANEKO, Tokyo (JP)

(73) Assignee: NEC Corporation, Minato-ku, Tokyo (JP)

(21) Appl. No.: 17/440,315

(22) PCT Filed: Feb. 14, 2020
(86) PCT No.: PCT/JP2020/005719

§ 371 Date: Sep. 17, 2021

(30) Foreign Application Priority Data
Mar. 28, 2019 (JP) 2019-062948

(51) Int. Cl. H05K 7/20; H05K 7/14

(52) U.S. Cl. CPC H05K 7/20809; H01L 23/427; H05K 7/1427

(57) ABSTRACT

To efficiently cool down heat of a heating element 20, this electronic device 100 is provided with a circuit board 10 having a heating element 20 that is attached to a first main surface 11 thereof, a case 30 having an opening part 31 that is formed in a surface facing the heating element 20 and housing a refrigerant COO therein, and a connection part 40 connecting the opening part 31 and the heating element 20 so as to enclose the refrigerant COO, the connecting part has a thickness of at most 0.21 mm.

### TECHNICAL FIELD

The present invention relates to an electronic device and the like, and for example, relates to a technique of an electronic device and the like that cool a heating element.

### BACKGROUND ART

In recent years, an amount of information processing has been increasing with development of technology such as a cloud service. In order to process the huge amount of information, a calculation amount of a heating element such as a central processing unit (CPU) and a multi-chip module (MCM) tends to increase. Accordingly, a heating amount of the heating elements also tends to increase. With this tendency, an effort for cooling the heating elements more efficiently is being made on a daily basis.

As a cooling technique for a heating element, an electronic device that uses a coolant for cooling a heating element is known (e.g., PTL 1).

A technique described in PTL 1 uses a vapor chamber for cooling a heating element. A heat receiving surface of the vapor chamber is mounted on the heating element. In the vapor chamber, a wick assembly formed by gathering a plurality of wicks is placed in an enclosed space (hydraulic fluid tank) between a case and a cover. A coolant (hydraulic fluid) is sealed in the enclosed space.

The vapor chamber receives heat of the heating element through the heat receiving surface. The heat of the heating element received through the heat receiving surface is transferred to the wicks. Accordingly, the coolant contained in the wicks boils and evaporates, undergoes a phase change from a liquid-phase state to a gas-phase state, and spreads to a cover side. The coolant spread to the cover side condenses and is liquefied on a cover wall surface, and undergoes a phase change from the gas-phase state to the liquid-phase state. Heat released as latent heat of condensation is released to the air through an outer surface of the cover. The liquefied coolant is refluxed to the heating element through the wicks by a capillary force and repeats evaporation and condensation in the enclosed space again.

Note that techniques related to the present invention are also disclosed in PTLs 2 to 5.

### CITATION LIST

### Patent Literature

[PTL 1] Japanese Unexamined Patent Application Publication No. 2008-153423
[PTL 2] Japanese Unexamined Patent Application Publication No. S59-188198
[PTL 3] Japanese Translation of PCT International Application Publication No. 2012-531056
[PTL 4] Japanese Unexamined Patent Application Publication No. H11-087586
[PTL 5] Japanese Unexamined Patent Application Publication No. S61-237993

### SUMMARY OF INVENTION

### Technical Problem

However, in the technique described in PTL 1, the heating element is mounted on the heat receiving surface of the vapor chamber and the heat of the heating element is transferred to the coolant through the case of the vapor chamber. At this time, a gap occurs between the heating element and the case of the vapor chamber, and thus the heat of the heating element is not sufficiently transferred to the coolant. Accordingly, a temperature rise of the coolant in the vapor chamber is suppressed. Consequently, there is a problem that the phase change of the coolant from the liquid-phase state to the gas-phase state is suppressed, and thus the heat of the heating element cannot be sufficiently cooled.

The present invention has been made in view of such circumstances, and an object of the present invention is to provide an electronic device and the like capable of cooling heat of a heating element more efficiently.

### Solution to Problem

An electronic device according to the present invention includes a circuit board with a heating element mounted on a main surface thereof, a case that is provided with an opening part being formed on a surface facing the heating element and houses a coolant, and a connection unit that connects the opening part and the heating element, thereby sealing the coolant, wherein a thickness of the connection unit is equal to or less than 0.21 mm.

### Advantageous Effects of Invention

The present invention is able to provide the electronic device capable of cooling heat of the heating element more efficiently.

### BRIEF DESCRIPTION OF DRAWINGS

FIG. 1 is a cross-sectional view of a configuration of an electronic device according to a first example embodiment of the present invention and illustrates a section at an A-A cutting plane in FIG. 4.

FIG. 2 is a cross-sectional view of the configuration of the electronic device according to the first example embodiment of the present invention and illustrates a section at a B-B cutting plane in FIG. 3.

FIG. 3 is a side view of the configuration of the electronic device according to the first example embodiment of the present invention.

FIG. 4 is a top view of the configuration of the electronic device according to the first example embodiment of the present invention.

FIG. 5 is a cross-sectional view of the configuration of an electronic apparatus according to the first example embodiment of the present invention and illustrates a section at a C-C cutting plane in FIG. 7.

FIG. 6 is a side view of the configuration of the electronic apparatus according to the first example embodiment of the present invention.

FIG. 7 is a front view of the configuration of the electronic apparatus according to the first example embodiment of the present invention.

FIG. 8 is a cross-sectional view of a configuration of a housing rack according to the first example embodiment of the present invention and illustrates a section at a D-D cutting plane in FIG. 9.

FIG. 9 is a front view of the configuration of the housing rack according to the first example embodiment of the present invention.

FIG. 10 is a cross-sectional view of a configuration of a first modification example of the electronic device according to the first example embodiment of the present invention.

FIG. 11 is a cross-sectional view of a configuration of an electronic device according to a second example embodiment of the present invention.

FIG. 12 is a cross-sectional view of a configuration of a first modification example of the electronic device according to the second example embodiment of the present invention.

FIG. 13 is a plan view of a configuration of a metal plate.

FIG. 14 is a cross-sectional view of a configuration of an electronic device according to a third example embodiment of the present invention.

FIG. 15 is a plan view of a configuration of a reticulated sheet as one example of a member constituting a coolant flow path.

FIG. 16 is a cross-sectional view of a configuration of an electronic device according to a fourth example embodiment of the present invention.

FIG. 17 is a plan view of a configuration of a laminated plate as one example of a member constituting a boiling acceleration unit and the coolant flow path.

FIG. 18 is a cross-sectional view of the configuration of the laminated plate as one example of the member constituting the boiling acceleration unit and the coolant flow path and illustrates a section at an E-E cutting plane in FIG. 17.

FIG. 19 is a cross-sectional view of a configuration of an electronic device according to a fifth example embodiment of the present invention and illustrates a section at an A1-A1 cutting plane in FIG. 22.

FIG. 20 is the cross-sectional view of the configuration of the electronic device according to the fifth example embodiment of the present invention and illustrates a section at a B1-B1 cutting plane in FIG. 21.

FIG. 21 is a side view of the configuration of the electronic device according to the fifth example embodiment of the present invention.

FIG. 22 is a top view of the configuration of the electronic device according to the fifth example embodiment of the present invention.

### EXAMPLE EMBODIMENT

### First Example Embodiment

An electronic device 100 according to a first example embodiment of the present invention is described based on the drawings.

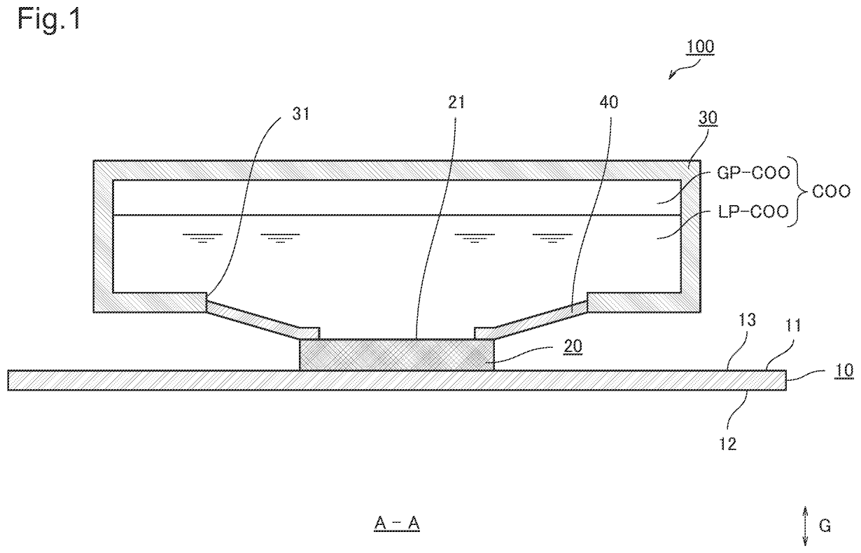

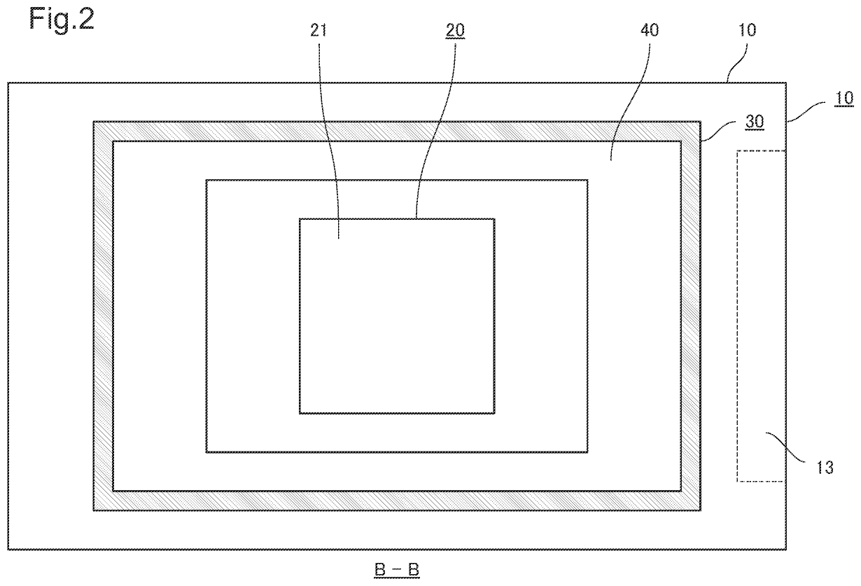

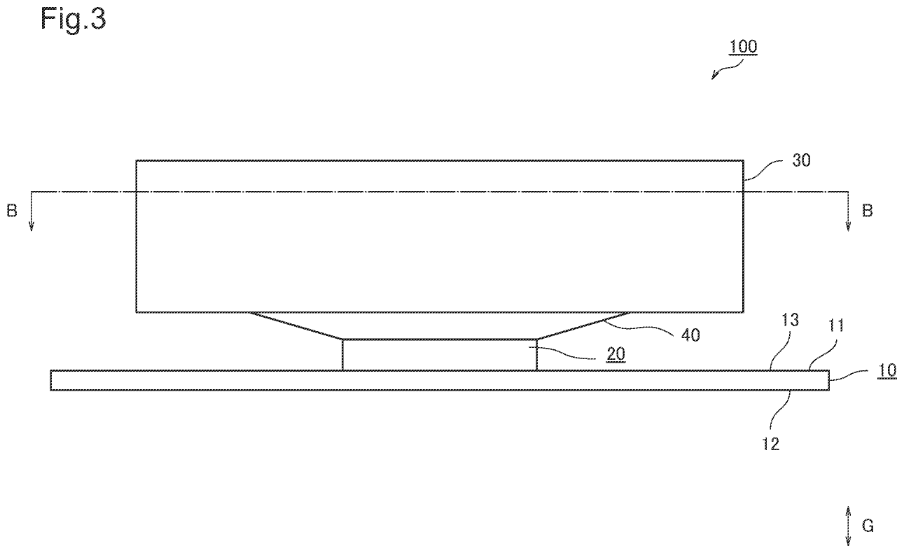

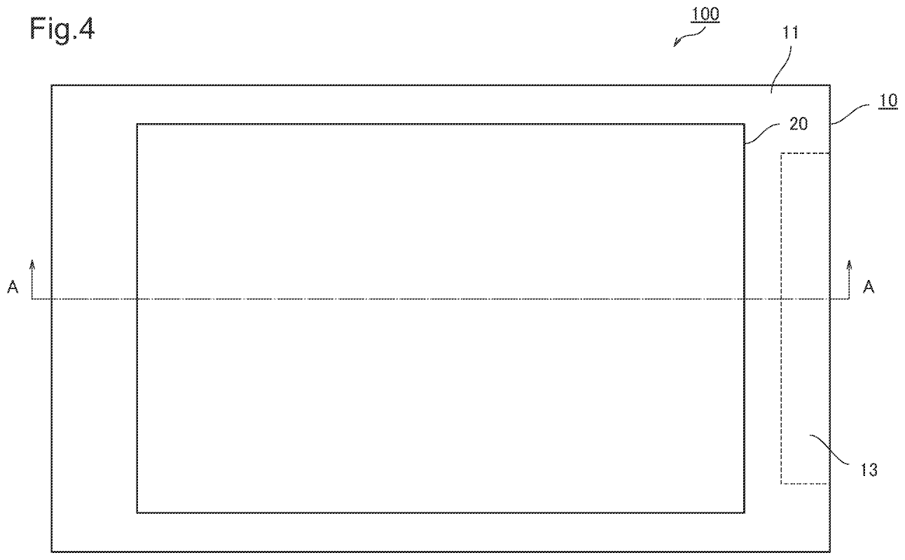

FIG. 1 is a cross-sectional view of a configuration of the electronic device 100 and illustrates a section at an A-A cutting plane in FIG. 4. FIG. 2 is a cross-sectional view of the configuration of the electronic device 100 and illustrates a section at a B-B cutting plane in FIG. 3. FIG. 3 is a side view of the configuration of the electronic device 100. FIG. 4 is a top view of the configuration of the electronic device 100. Note that a vertical direction G is illustrated in FIGS. 1 and 3.

The electronic device 100 includes a circuit board 10, a case 30, and a connection unit 40 with reference to FIGS. 1 to 4. Note that the electronic device 100 can be used as an electronic module to be incorporated in a communication device, a server, and the like, for example.

The circuit board 10 is formed in a plate shape. The circuit board 10 includes a first main surface 11, a second main surface 12, and a connector portion 13. Herein, the main surface of the circuit board 10 is a major surface of the circuit board 10, for example, a surface on which an electronic component is mounted. Note that the first main surface 11 may be referred to as a front surface of the circuit board and the second main surface 12 may be referred to as a back surface of the circuit board. A heating element 20 is mounted on the first main surface 11 of the circuit board 10.

The circuit board 10 is, for example, a printed wiring board. The printed wiring board is configured by laminating a plurality of insulating substrates and conductive wiring. Further, a conductive pad for mounting an electronic component is formed on the first main surface 11 and the second main surface 12 of the circuit board 10. As a material for the insulating substrate, phenolic resin or glass epoxy resin is used, for example. The conductive wiring and the conductive pad are formed of a copper film, for example.

Further, the connector portion 13 is formed on the first main surface 11 of the circuit board 10, for connecting to another electronic component (not illustrated). The connector portion 13 is configured of, for example, a plurality of terminals (not illustrated) formed on the first main surface 11 of the circuit board 10. Note that the connector portion 13 may also be formed on the second main surface 12. In this case, the connector portion 13 is formed in an area of the second main surface 12 corresponding to a forming area of the connector portion 13 formed on the first main surface 11. Note that the connector portion 13 is not an essential component according to the present example embodiment.

The heating element 20 is mounted on the first main surface 11 of the circuit board 10. The heating element 20 includes a first heating element outer surface 21. The first heating element outer surface 21 is one of outer surfaces of the heating element 20 and is a surface opposite to a circuit board 10 side among the surfaces of the heating element 20. The first heating element outer surface 21 is generally a plane surface but may be a curved surface. Note that the heating element 20 is a component that generates heat during operation, such as a central processing device CPU or an integrated circuit MCM.

As illustrated in FIG. 1, the case 30 is formed in a box shape including an opening part 31. The case 30 houses a coolant COO. The inside of the case 30 is hollow. The coolant COO is provided in the hollow. The opening part 31 is, among surfaces constituting the case 30, formed on a surface facing the first main surface 11 of the circuit board 10. The opening part 31 is usually provided at a position facing the heating element 20. Further, as a material of the case 30, a heat conductive member is used such as aluminum, aluminum alloy, copper, and copper alloy. A thickness of the case 30 may be, but not limited to, 1 mm to 2 mm, for example, considering manufacturing efficiency, weight, and the like.

The connection unit 40 is formed by a heat conductive member. As a material of the connection unit 40, copper, copper alloy, silver, silver alloy, gold, gold alloy, aluminum, aluminum alloy, or the like is used, for example, as the heat conductivity member. The connection unit 40 is a plate or foil. It is known that aluminum foil, aluminum alloy foil and copper foil generally available are equal to or less than about 0.2 mm thick. In other words, a nominal thickness of the aluminum foil and aluminum alloy foil is defined as equal to or less than 0.2 mm (Japanese Industrial Standards (JIS H4160: 2006)). As a reference, a nominal thickness of the copper foil for a printed wiring board is defined as equal to or less than 0.21 mm (Japanese Industrial Standards (JIS C6515: 1998)).

Further, the connection unit 40 connects the opening part 31 of the case 30 and the heating element 20, thereby sealing the coolant COO. The connection unit 40 is placed between the case 30 and the heating element 20, and connects the case 30 and the heating element 20.

One end part of the connection unit 40 is attached on an outer peripheral part of the first heating element outer surface 21 of the heating element 20 by fixing with an adhesive or a screw, for example. Thus, the one end part of the connection unit 40 and the outer peripheral part of the first heating element outer surface 21 of the heating element 20 are joined. Another end part of the connection unit 40 is attached on the opening part 31 of the case 30 by fixing with an adhesive or a screw, for example. Thus, the another end part of the connection unit 40 and the opening part 31 of the case 30 are joined. The joining of the parts enables an inner part of the case 30 to be sealed, and thus leakage of the coolant COO can be suppressed. Note that the one end part of the connection unit 40 is at a position lower than the another end part of the connection unit 40 in the vertical direction G, and thus, the one end part of the connection unit 40 is also a lower end part of the connection unit 40. The another end part of the connection unit 40 is at a position upper than the one end part of the connection unit 40 in the vertical direction G, and thus, the another end part of the connection unit 40 is also a top end part of the connection unit 40.

Note that grease may be interposed between the one end part of the connection unit 40 and the outer peripheral part of the first heating element outer surface 21 of the heating element 20. The interposing of the grease prevents a gap from occurring between the one end part of the connection unit 40 and the outer peripheral part of the first heating element outer surface 21 of the heating element 20. Consequently, the leakage of the coolant COO from the gap between the one end part of the connection unit 40 and the outer peripheral part of the first heating element outer surface 21 of the heating element 20 can be suppressed.

Further, the grease may be interposed between the another end part of the connection unit 40 and the opening part 31 of the case 30. The interposing of the grease prevents a gap from occurring between the another end part of the connection unit 40 and the opening part 31 of the case 30. Consequently, the leakage of the coolant COO from the gap between the another end part of the connection unit 40 and the opening part 31 of the case 30 can be suppressed.

As the coolant COO, a coolant that undergoes a phase change between a coolant in a liquid-phase state (liquid-phase coolant, hereinafter, referred to as LP-COO) and a coolant in a gas-phase state (gas-phase coolant, hereinafter, referred to as GP-COO) is used.

As the coolant COO, hydro fluorocarbon (HFC), hydro fluoroether (HFE), or the like can be used, for example.

The coolant COO is contained, in a sealed state, in a space where the opening part 31 of the case 30 is sealed with the first heating element outer surface 21 of the heating element 20 and the connection unit 40. Accordingly, vacuum evacuation is performed after injecting the liquid-phase coolant LP-COO into the sealed space enclosed by the inner part of the case 30, the heating element 20, and the connection unit 40, and thus a saturated vapor pressure of the coolant can be maintained in the sealed space. A method of filling the coolant COO into the sealed space enclosed by the inner part of the case 30, the heating element 20, and the connection unit 40 is described later in detail in a description about a manufacturing method of the electronic device 100.

The configuration of the electronic device 100 is described above.

Next, the manufacturing method of the electronic device 100 is described.

First, the circuit board 10 on which the heating element 20 is mounted is prepared. Next, the opening part 31 of the case 30 and the heating element 20 are connected by the connection unit 40. In other words, the one end part of the connection unit 40 is attached on the outer peripheral part of the first heating element outer surface 21 of the heating element 20 by fixing with an adhesive or a screw, for example. Further, the another end part of the connection unit 40 is mounted on the opening part 31 of the case 30 by fixing with an adhesive or a screw, for example. Accordingly, the heating element 20 and the opening part 31 of the case 30 are connected by the connection unit 40. Consequently, the sealed space is formed by the inner part of the case 30, the heating element 20, and the connection unit 40.

Next, the coolant COO is filled in the space enclosed by the case 30, the heating element 20, and the connection unit 40.

The method of filling the coolant COO in the space enclosed by the case 30, the heating element 20, and the connection 40 is as follows.

The coolant COO is injected into the space enclosed by the case 30, the heating element 20, and the connection unit 40 through a coolant injection hole (not illustrated) previously provided on a top surface (a surface on upper side of the page in FIG. 1) of the case 30. Then, the coolant injection hole is closed. Further, air is removed from the space enclosed by the case 30, the heating element 20, and the connection unit 40, using a vacuum pump (not illustrated) or the like through the air removal hole (not illustrated) previously provided on the top surface (the surface on upper side of the page in FIG. 1) of the case 30. Then, the air removal hole is closed. In this manner, the coolant COO is sealed in the space enclosed by the case 30, the heating element 20, and the connection unit 40. Accordingly, a pressure in the space enclosed by the case 30, the heating element 20, and the connection unit 40 becomes equal to the saturated vapor pressure of the coolant COO, and the coolant COO sealed in the space enclosed by the case 30, the heating element 20, and the connection unit 40 becomes in a vapor-liquid equilibrium state. Note that the coolant injection hole may be shared as the air removal hole.

The manufacturing method of the electronic device 100 is described as above.

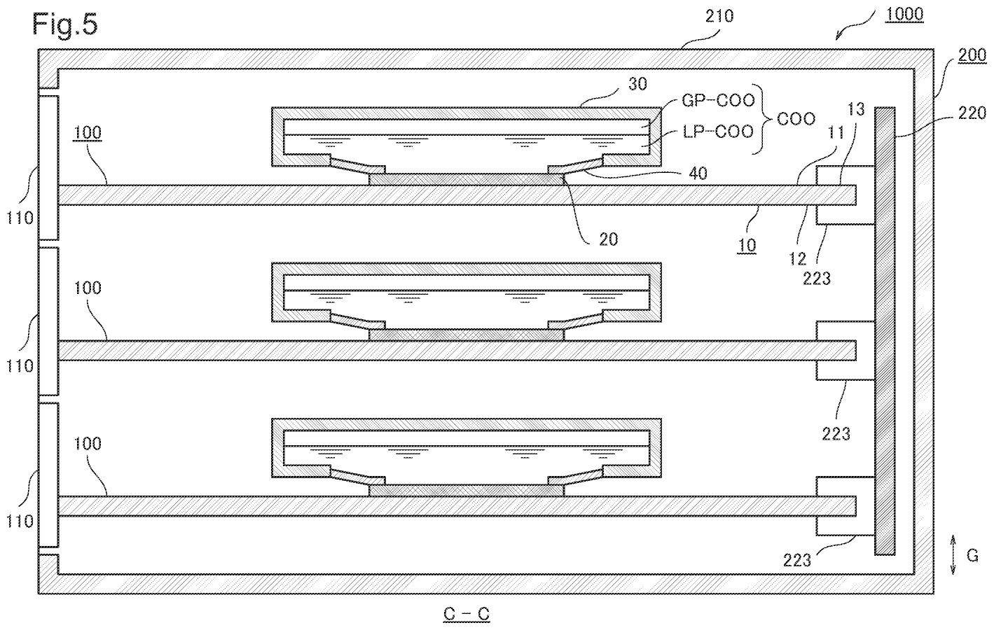

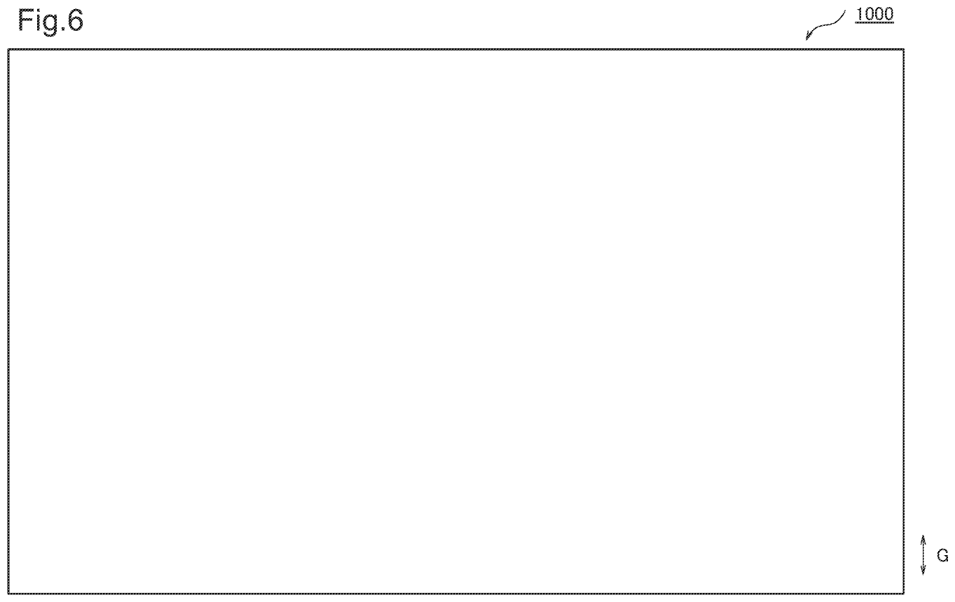

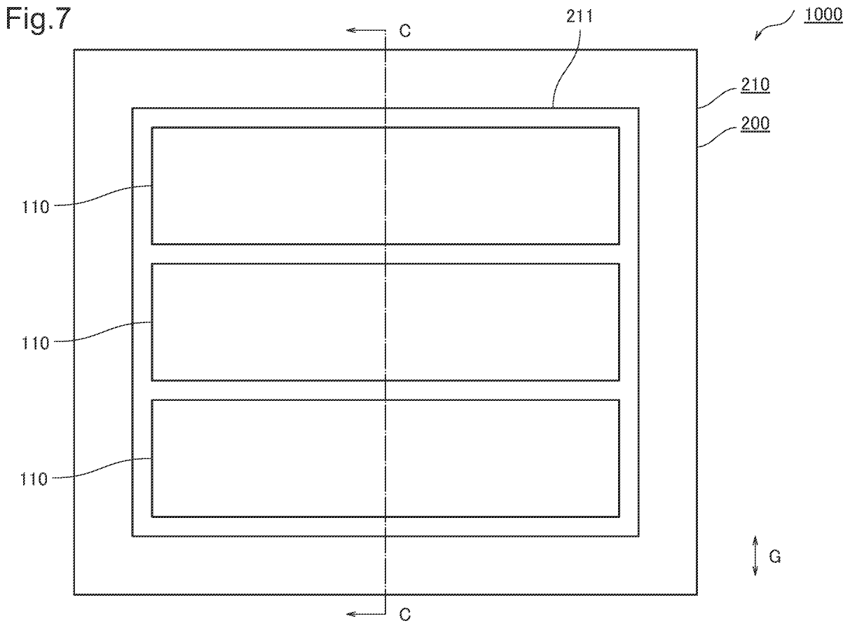

Next, a configuration of an electronic apparatus 1000 according to the first example embodiment of the present invention is described. FIG. 5 is a cross-sectional view of the configuration of the electronic apparatus 1000 and illustrates a section at a C-C cutting plane in FIG. 7. FIG. 6 is a side view of the configuration of the electronic apparatus 1000. FIG. 7 is a front view of the configuration of the electronic apparatus 1000. In FIGS. 5 and 6, a left side is a front side of the electronic apparatus 1000 and a right side is a back side of the electronic apparatus 1000. Note that the vertical direction G is illustrated in FIGS. 5 to 7.

Referring to FIGS. 5 to 7, the electronic apparatus 1000 includes the electronic device 100 and a housing rack 200. Note that the electronic apparatus 1000 is a communication device, a server, or the like, for example. One or more electronic devices 100 (electronic module and the like) are incorporated in the electronic apparatus 1000.

As illustrated in FIG. 5, the housing rack 200 houses a plurality of electronic devices 100. In FIG. 5, three electronic devices 100 are housed in the housing rack 200. The number of electronic devices, however, is not limited to three, and one or a plurality of electronic devices 100 may be housed in the housing rack 200.

Herein, as illustrated in FIGS. 5 and 7, a front cover 110 is mounted on an end part opposite to the connector portion 13 on the circuit board 10 of the electronic device 100. Note that the front cover 110 is not an essential component of the present example embodiment.

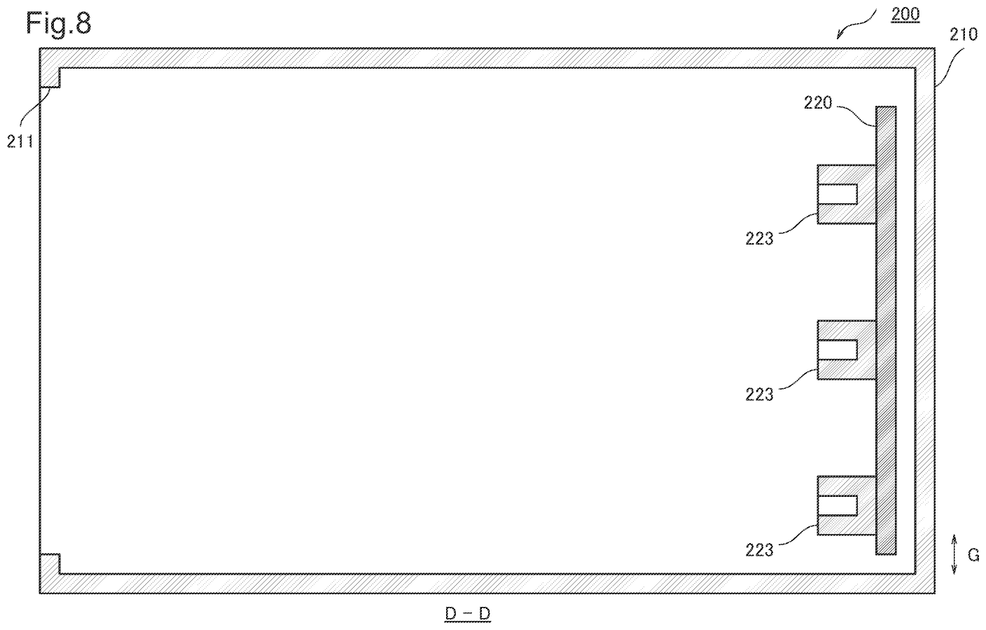

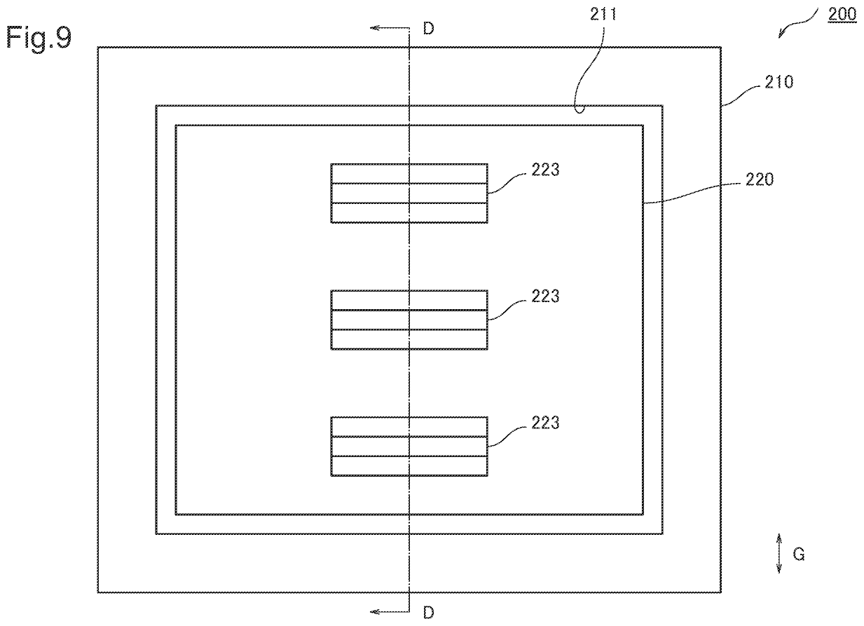

A configuration of the housing rack 200 is specifically described. FIG. 8 is a cross-sectional view of the configuration of the housing rack 200 and illustrates a section at a D-D cutting plane in FIG. 9. FIG. 9 is a front view of the configuration of the housing rack 200. Note that the vertical direction G is illustrated in FIGS. 8 and 9.

As illustrated in FIGS. 8 and 9, the housing rack 200 includes a case 210 and a circuit board 220.

The case 210 is formed in a box shape with an inside thereof being hollow. The case 210 houses the circuit board 220. The case 210 includes an opening part 211. The opening part 211 is formed on the front surface side of the housing rack 200. The circuit board 220 and the electronic device 100 are housed in the case 210 through the opening part 211. As a material of the case 210, aluminum, aluminum alloy, stainless alloy, or the like is used, for example.

The circuit board 220 is fixed to an inner part of a back surface side of the case 210 by a screw or the like. The circuit board 220 is placed along the vertical direction G. Further, as illustrated in FIG. 8, a housing-rack-side connector portion 223 is mounted on the circuit board 220. The housing-rack-side connector portion 223 is provided in such a way as to fit with the connector portion 13. Specifically, a thickness of the circuit board 10 at a position where the connector portion 13 is placed, and a width of a part of the housing-rack-side connector portion 223 for housing the connector portion 13 are set to be substantially equal to each other. Further, a pitch distance between terminals (not illustrated) provided on the connector portion 13 and a distance between terminals (not illustrated) of the housing-rack-side connector portion 223 are set to be substantially equal to each other.

The configuration of the housing rack 200 is described above.

Next, an operation of the electronic device 100 and the electronic apparatus 1000 are described. As illustrated in FIG. 5, the electronic device 100 is housed in the case 210 of the housing rack 200. At this time, the connector portion 13 of the electronic device 100 is inserted into the housing-rack-side connector portion 223 of the housing rack 200. Thus, the connector portion 13 is fitted with the housing rack-side connector 223. Consequently, the connector portion 13 and the housing rack-side connector portion 223 are electrically connected. Further, the circuit board 220 of the housing rack 200 and the circuit board 10 of the electronic device 100 are electrically connected through the connector portion 13 and the housing-rack-side connector portion 223.

Next, when the electronic apparatus 1000 is activated, power is supplied from the circuit board 220 to the electronic device 100 through the housing-rack-side connector portion 223 and the connector portion 13. Thus, the electronic device 100 is activated.

When the electronic device 100 is activated, power is supplied to the heating element 20 on the circuit board 10. Thus, the heating element 20 generates heat.

Herein, the first heating element outer surface 21 of the heating element 20 is in contact with the liquid-phase coolant LP-COO in the case 30. Accordingly, the liquid-phase coolant LP-COO being stored in the lower side of the case 30 in the vertical direction G boils on the first heating element outer surface 21 of the heating element 20 by the heat of the heating element 20, and turns to the gas-phase coolant GP-COO by a phase change. Thus, air bubbles of the gas-phase coolant GP-COO are generated. The heating element 20 is cooled by heat of vaporization (latent heat) to be generated by the phase change.

Further, the first heating element outer surface 21 of the heating element 20 is connected to the opening part 31 of the case 30 through the connection unit 40 formed by a heat conductive member. Accordingly, the heat from the heating element 20 is transferred to the case 30 through the connection unit 40. Consequently, the heating element 20 is cooled.

Further, the connection unit 40 is in contact with the liquid-phase coolant LP-COO in the case 30. Accordingly, the liquid-phase coolant LP-COO being stored in the lower side of the case 30 in the vertical direction G boils on the connection unit 40 by the heat of the heating element 20, and turns to the gas-phase coolant GP-COO by the phase change. Thus, air bubbles of the gas-phase coolant GP-COO are generated.

The gas-phase coolant GP-COO rises upward in the vertical direction G through the liquid-phase coolant LP-COO in the case 30 through the connection unit 40, passes through a liquid surface of the liquid-phase coolant LP-COO, and further rises upward in the vertical direction G. When the gas-phase coolant GP-COO boiled by the heat of the heating element 20 is cooled by contact with an inner wall surface of the case 30, the gas-phase coolant GP-COO turns to the liquid-phase coolant LP-COO again by the phase change. The liquid-phase coolant LP-COO falls downward in the vertical direction G in the case 30, is stored on the circuit board 10 side, and is used again for cooling the heating element 20.

The operation of the electronic device 100 and the electronic apparatus 1000 are described above.

As described above, the electronic device 100 according to the first example embodiment of the present invention includes the circuit board 10, the case 30, and the connection unit 40. The heating element 20 is mounted on the first main surface 11 of the circuit board 10. The case 30 includes the opening part 31 and houses the coolant COO. The opening part 31 is formed on the surface facing the heating element 20 among the surfaces constituting the case 30. The connection unit 40 is formed by the heat conductive member. The connection unit 40 connects the opening part 31 and the heating element 20, thereby sealing the coolant COO.

In this manner, in the electronic device 100 according to the first example embodiment of the present invention, the opening part 31 and the heating element 20 are connected and the coolant COO is sealed. Accordingly, the heating element 20 can contact directly with the coolant COO in the case 30. Thus, the heat of the heating element 20 is transferred efficiently to the coolant COO in the case 30, thereby accelerating the phase change of the coolant COO more efficiently. Consequently, the electronic device 100 according to the first example embodiment of the present invention is able to cool the heat of the heating element more efficiently.

Further, a distance between the case 30 and the heating element 20 can be increased by providing the connection unit 40. A volume for housing the coolant COO can also be increased by providing the connection unit 40. Further, a size of the opening part 31 can be larger than a size of the first heating element outer surface 21 of the heating element 20. Furthermore, by interposing the connection unit 40 between the case 30 and the heating element 20, it is possible to absorb dimensional variations that occur during manufacturing of the case 30 and the heating element 20, and deformation of the heating element 20 during heat generation.

A thickness of the connection unit 40 is equal to or less than 0.21 mm. Thus, the connection unit 40 can be formed into foil by a main metal material such as aluminum, aluminum alloy, and copper. Consequently, the connection unit 40 can be more flexible, and the opening part 31 can be easily connected to the first heating element outer surface 21 of the heating element 20.

Herein, in the technique described in PTL 1, the heating element is mounted on the heat receiving surface of the vapor chamber and the heat of the heating element is transferred to the coolant through the case of the vapor chamber as described above. At this time, a gap occurs between the heating element and the case of the vapor chamber, and thus the heat of the heating element is not sufficiently transferred to the coolant. A temperature rise of the coolant in the vapor chamber is suppressed, the phase change of the coolant from the liquid-phase state to the gas-phase state is suppressed, and the heat of the heating element cannot be sufficiently cooled.

In contrast, in the electronic device 100 according to the first example embodiment of the present invention, the heating element 20 can contact directly with the coolant COO in the case 30, as described above. Thus, the heat of the heating element 20 can be transferred directly to the coolant COO in the case 30 without passing through the surface (bottom surface) of the case 30 on the heating element 20 side or the gap between the bottom surface of the case 30 and the heating element 20. Consequently, the electronic device 100 according to the first example embodiment of the present invention is able to cool the heat of the heating element 20 more efficiently, compared with the invention described in PTL 1.

Further, in a technique described in PTL 2, at least a heating component is incorporated in an electronic circuit package, a cover is provided in such a way that a sealing container in which the cover serves as a part of a wall of a component mounting surface of the package is formed, and the entire heating component is immersed by injecting a cooling liquid into the cover. More specifically, in the technique described in PTL 2, only a part of an area on one surface of a circuit board that includes a heating element is covered with a case, thereby sealing the heating element and a coolant between the one surface of the circuit board and the case. In this manner, a configuration in which only a part of the circuit board is covered with the case and only the part of the circuit board is immersed in the coolant is adopted. Thus, the technique described in PTL 2 is able to reduce an amount of coolant, thereby reducing a weight of the electronic device. Further, in the technique described in PTL 2, an iron core is used for the circuit board, thereby suppressing the coolant from leaking out through the circuit board. Note that the technique described in PTL 2 is referred to as a partial immersion cooling.

In contrast, the electronic device 100 according to the first example embodiment of the present invention uses a circuit board made of phenolic resin or glass epoxy resin for the circuit board 10 without using an iron core. However, the electronic device 100 according to the first example embodiment of the present invention connects the opening part 31 and the heating element 20 by the connection unit 40, thereby sealing the coolant COO. Thus, even though the circuit board made of phenolic resin or the glass epoxy resin is used for the circuit board 10, the coolant COO can be prevented from leaking out through the circuit board 10.

In a technique described in PTL 3, a heating element (a heating electronic device 510) is mounted on a circuit board (a printed circuit board 540). A housing (a module casing 530, an uppermost wall 571 of a housing) houses a heating element, and is mounted on one surface of the circuit board in such a way as to seal a coolant (a dielectric cooling liquid 532) between the housing and the one surface of the circuit board. Further, two pumps (impingement cooling type immersible pumps 535 and 536) are placed in the coolant in the housing and circulate the coolant. Further, a cooling mechanism (a liquid cooling cold plate 420) is mounted on an upper surface of the housing (the uppermost wall 571 of the housing). In the cooling mechanism, another coolant different from the coolant in the housing flows from a suction port toward a discharge port. In this manner, in the technique described in PTL 3, the heat of the heating element is cooled by circulating the coolant within the housing, and flowing, into the cooling mechanism, the another coolant different from the coolant in the housing.

In the techniques described in PTLs 2 and 3, the entire heating element is immersed in the coolant in the case.

In contrast, in the electronic device 100 according to the first example embodiment of the present invention, the opening part 31 and the heating element 20 are connected by the connection unit 40, thereby sealing the coolant COO, and thus, only the heating element 20 (specifically, the first heating element outer surface 21) comes into contact with the coolant COO in the case 30. In other words, the heating element 20 is not immersed entirely in the coolant in the case 30.

Thus, the electronic device 100 according to the first example embodiment of the present invention is configured in such a way that only a part of the surfaces of the heating element 20 comes into contact with the coolant in the case 30, thereby reducing an amount of coolant, compared with the techniques described in PTLs 2 and 3.

Further, in the electronic device 100 according to the first example embodiment of the present invention, it is not necessary to immerse the entire heating element in the coolant COO. Thus, in the electronic device 100, the heating element 20 can be easily removed from the circuit board 10 when the heating element 20 or the like are replaced, compared with the technique described in PTL 1.

Further, in the electronic device 100 according to the first example embodiment of the present invention, the connection unit 40 is formed by a heat conductive component. Accordingly, the heat of the heating element 20 can be transferred efficiently to the case 30 through the connection unit 40. In other words, the heat of the heating element 20 can be transferred to the case 30 more efficiently than a case where the connection unit 40 is formed by a non-heat-conductive member. Consequently, the heat of the heating element 20 can be cooled more efficiently.

Further, in the electronic device 100 according to the first example embodiment of the present invention, it is possible to use a coolant COO capable of turning to the liquid-phase coolant LP-COO and the gas-phase coolant GP-COO by the phase change. Thus, not only sensible heat transfer by a temperature change of the coolant COO but also latent heat transfer by the phase change is used, thereby increasing cooling efficiency of the heating element 20, compared with a coolant without the phase change.

The electronic device 100 according to the first example embodiment of the present invention further includes the connector portion 13. The connector portion 13 is provided at an end part on the first main surface 11 of the circuit board 10, and is connected to another electronic component (e.g., housing rack-side connector portion 223). Further, the case 30 is mounted on the first main surface 11 in such a way as not to cover the connector portion 13. Specifically, the case 30 is mounted on a portion of the first main surface 11 other than the position where the connector portion 13 is mounted. Note that the connector portion 13 is provided on, but not limited to, the first main surface 11, and may be provided on the second main surface 12.

Thus, the case 20 is mounted on the first main surface 11 of the circuit board 10 in such a way as not to interfere with the connector portion 13. Consequently, it is possible to prevent the case 20 from obstructing connection between the another electronic component and the connector portion 13. Further, the another electronic component and the connector portion 13 can be connected without removing the case 30, and thus, it is easy to perform maintenance operation such as repair of an electronic component on the circuit board 10.

Further, the electronic apparatus 1000 according to the first example embodiment of the present invention includes the electronic device 100 and the housing rack 200. The electronic device 100 is mounted on the housing rack 200. Thus, the electronic apparatus 1000 incorporating the electronic device 100 can be configured, and it is possible to provide an advantageous effect similar to the advantageous effect of the above-described electronic device 100.

Further, the electronic apparatus 1000 according to the first example embodiment of the present invention includes the electronic device 100 and the housing rack 200. The electronic device 100 is mounted on the housing rack 200. The housing rack 200 further includes the housing-rack-side connector portion 223 to be connected to the connector portion 13. Thus, it is possible to electrically connect the electronic device 100 and the housing rack 200 through the connector portion 13 and the housing-rack-side connector portion 223. Thus, the electronic apparatus 1000 incorporating the electronic device 100 can be configured, and it is possible to provide an advantageous effect similar to the advantageous effect of the above-described electronic device 100.

Note that a heat radiating unit (not illustrated) may be further provided on the top surface (the surface on upper side of the page in FIG. 1) of the case 30. The heat radiating unit is configured of a heat sink having a fin structure, for example. Thus, the heat radiating unit can efficiently radiate the heat of the heating element 20 transferred to the case 30 toward the outside air. Further, a fan may also be provided in order to send cooling air to the heat sink configuring the heat radiating unit.

Further, the coolant COO may be forcibly convected within the case 30 by providing a fan (not illustrated) and a pump (not illustrated) in the case 30. Thus, it is possible to accelerate more efficient circulation of the coolant COO within the case 30. Consequently, the heat of the heating element 20 can be cooled more efficiently.

A case where the heating element 20 is a three-dimensional semiconductor is described. A typical three-dimensional semiconductor is configured in such a way that a die is mounted on a base. In this case, the die is mounted on the circuit board 10 by soldering, crimping by a spring member, or the like. Further, the base is mounted on the die by soldering or crimping by a spring member. In this case, the connection unit 40 connects the base and the opening part 31.

On the other hand, the connection unit 40 may connect the die and the opening part 31. In this case, a circuit board according to the present example embodiment may be a circuit board 20 on which the base is mounted or a base on which the die is mounted.

### First Modification Example of First Example Embodiment

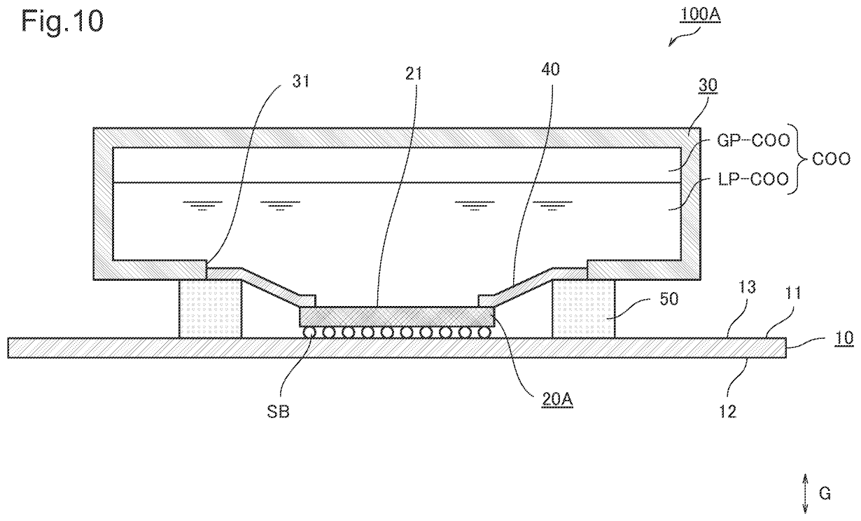

A configuration of an electronic device 100A being a first modification example of the electronic device according to the first example embodiment of the present invention is described based on the drawings. FIG. 10 is a cross-sectional view of the configuration of the electronic device 100A. FIG. 10 is the cross-sectional view associated with FIG. 1. Note that a vertical direction G is illustrated in FIG. 10. Further, in FIG. 10, a component equivalent to each component illustrated in FIGS. 1 to 9 is indicated with a same reference sign as the reference sign illustrated in FIGS. 1 to 9.

Referring to FIG. 10, the electronic device 100A includes a circuit board 10, a heating element 20A, a case 30, a connection unit 40, and a holding unit 50. The electronic device 100A can be attached to a housing rack 200 similarly to the electronic device 100. Note that the electronic device 100A can be used as an electronic module to be incorporated in a communication device, a server, and the like, for example.

Herein, comparison is made between the electronic device 100A and the electronic device 100. As illustrated in FIG. 10, the electronic device 100A is different from the electronic device 100 in that the electronic device 100A includes the holding unit 50.

Referring to FIG. 10, the holding unit 50 is mounted on a first main surface 11 of the circuit board 10 and holds the case 30 along an opening part 31. The holding unit 50 is placed between the first main surface 11 of the circuit board 10 and a bottom surface of the case 30. The holding unit 50 is formed in a frame shape. The holding unit 50 is mounted on the circuit board 10 by fixing with an adhesive or a screw, for example. Further, among surfaces of the case 30, a surface facing the first main surface 11 of the circuit board 10 is attached to the holding unit 50 along the opening part 31 by fixing with an adhesive or a screw, for example. Further, another end part of the connection unit 40 may be joined to the case 30 and may also be fixed to the holding unit 50. The holding unit 50 is also referred to as a stiffener.

As described above, in the electronic device 10 being the first modification example of the electronic device according to the first example embodiment, the holding unit 50 is mounted on the first main surface 11 of the circuit board 10 and holds the case 30 along the opening part 31. Thus, the case 30 can be mounted on the first main surface of the circuit board 10 through the holding unit 50. This configuration prevents the case 30 from moving with respect to the circuit board 10 or coming off the circuit board 10. For example, a load applied to a joint part of the connection unit 40 and the opening part 31 by weight of the case 10 and the coolant COO can be suppressed. Thus, the connection unit 40 can be prevented from coming off the case 30 near the joint part of the connection unit 40 and the opening part 31. Consequently, the leakage of the coolant COO from the joint part of the connection unit 40 and the opening part 31 can be suppressed.

### Second Example Embodiment

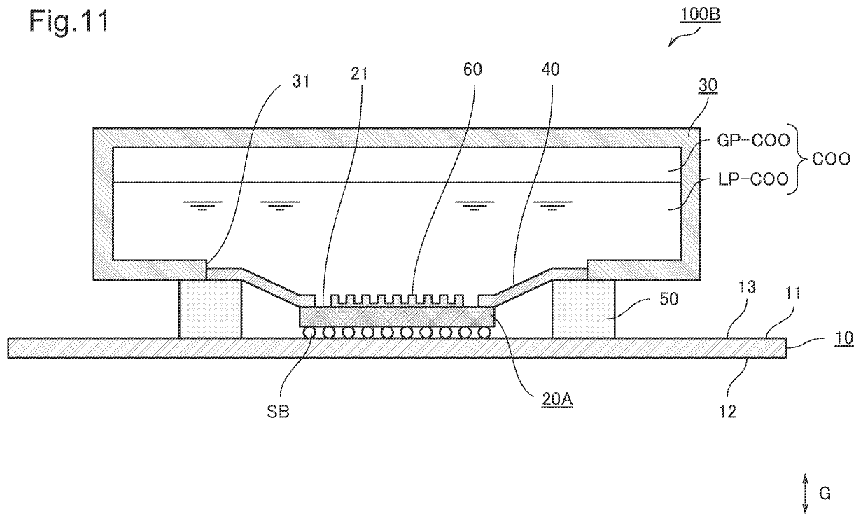

A configuration of an electronic device 100B according to a second example embodiment of the present invention is described based on the drawings. FIG. 11 is a cross-sectional view of the configuration of the electronic device 100B. FIG. 11 is the cross-sectional view associated with FIG. 1. Note that a vertical direction G is illustrated in FIG. 11. Further, in FIG. 11, a component equivalent to each component illustrated in FIGS. 1 to 10 is indicated with a same reference sign as the reference sign illustrated in FIGS. 1 to 10.

Referring to FIG. 11, the electronic device 100B includes a circuit board 10, a heating element 20A, a case 30, a connection unit 40, a holding unit 50, and a boiling acceleration unit 60. The electronic device 100B can be attached to a housing rack 200 similarly to the electronic device 100. Note that the electronic device 100B can be used as an electronic module to be incorporated in a communication device, a server, and the like, for example.

Herein, comparison is made between the electronic device 100B and the electronic device 100A. As illustrated in FIG. 11, the electronic device 100B is different from the electronic device 100A in that the electronic device 100B includes the boiling acceleration unit 60. Further, in the electronic device 100B, the heating element 20A is different from a heating element 20 being configured of a normal package in that the heating element 20A is configured of a ball grid array (BGA) type integrated circuit (IC) package.

Referring to FIG. 11, the heating element 20A is connected by a solder ball (hereinafter, referred to as SB). Note that, in the electronic device 100B, the heating element 20 may be used instead of the heating element 20A.

Referring to FIG. 11, the boiling acceleration unit 60 is provided on a first heating element outer surface 21 of the heating element 20A. The boiling acceleration unit 60 accelerates a phase change from a liquid-phase coolant LP-COO near the first heating element outer surface 21 to a gas-phase coolant GP-COO by heat of the heating element 20A.

Herein, the boiling acceleration unit 60 is a plate member formed of metal or resin having a plurality of grooves or a porous body. Further, the boiling acceleration unit 60 is mounted on the first heating element outer surface 21 by fixing with an adhesive or a screw. Note that the boiling acceleration unit 60 may be grooves or the porous body formed on the first heating element outer surface 21, for example. In other words, the boiling acceleration unit 60 may be fixed to the first heating element outer surface 21 by a separated body or may be formed by processing the first heating element outer surface 21 in such a way as to be integrated with the heating element 20A. Note that the porous body is formed with a plurality of micropores.

The porous body may be configured of a sintered body or a mesh, for example. The sintered body is an object formed by compacting an aggregate of solid powders and the plurality of micropores are formed among the solid powders by bonding particles of the solid powders. The sintered body is formed on an upper surface of the heating element 20A by sintering the solid powders. Sintering is the process of compacting the solid powders by heating the aggregate of solid powders at a temperature lower than a melting point of the solid powder. The mesh is formed, for example, by a reticulated metal sheet.

Note that, as a material of the sintered body, ceramic, aluminum, stainless steel, copper, brass, bronze or the like is used, for example. As a main component of ceramic, alumina, yttria (yttrium oxide), aluminum nitride, boron nitride, silicon carbide, silicon nitride or the like is used. As a material for the mesh, metal such as aluminum, aluminum alloy, copper, and copper alloy is used, for example.

According to the present example embodiment, the boiling acceleration unit 60 is preferably integrated with the heating element 20A by processing the first heating element outer surface 21 rather than being fixed to the first heating element outer surface 21 by a separate body. When the boiling acceleration unit 60 is configured in such a way as to be fixed to the first heating element outer surface 21 by a separate body, a gap may occur between the boiling acceleration unit 60 and the heating element 20A, and the heat of the heating element 20A may not be sufficiently transferred to the boiling acceleration unit 60. In contrast, when the boiling acceleration unit 60 is formed by processing the first heating element outer surface 21 in such a way as to be integrated with the heating element 20A, a gap does not occur between the boiling acceleration unit 60 and the heating element 20A, and thus, the heat of the heating element 20A can be transferred more efficiently by the boiling acceleration unit 90.

By providing the boiling acceleration unit 60 on the first heating element outer surface 21 of the heating element 20A, a boiling nucleus (=a trigger for boiling) can be formed on the heating element 20A, and a superheating state (=a state in which boiling does not occur even when a boiling point is exceeded) can be suppressed. Thus, the heat of the heating element 20A is more efficiently transferred to the liquid-phase coolant LP-COO around the first heating element outer surface 21. Consequently, the liquid-phase coolant LP-COO around the first heating element outer surface 21 can turn to the gas-phase coolant GP-COO by the phase change more efficiently, compared with a case where the boiling acceleration unit 60 is not provided.

In particular, a heat exchange area with the coolant COO can be increased by providing the boiling acceleration unit 60. Specifically, when the boiling acceleration unit 60 is not provided, the heat exchange area with the coolant COO is the area of the first heating element outer surface 21 of the heating element 20A. Herein, a surface area of the boiling acceleration unit 60 including the grooves and the porous body thereof is larger than the surface area of the first heating element outer surface 21 of the heating element 20A. Accordingly, when the boiling acceleration unit 60 is provided, the heat exchange area with the coolant COO becomes larger, compared with the case where the boiling acceleration unit 60 is not provided. Consequently, the heat of the heating element 20A can be transferred more efficiently to the coolant COO.

The configuration of the electronic device 100B is described as above.

Next, a manufacturing method of the electronic device 100B is described.

First, the circuit board 10 on which the heating element 20A is mounted is prepared. Next, the holding unit 50 is mounted on a first main surface 11 of the circuit board 10. An opening part 31 of the case 30 and the heating element 20 are connected by the connection unit 40. Consequently, a space enclosed by an inner part of the case 30, the heating element 20, and the connection unit 40 can be formed. At this time, a top surface (the surface on upper side of the page in FIG. 11) of the case 30 is formed in such a way as to be removable.

Then, in a state where the top surface of the case 30 is removed, the boiling acceleration unit 60 is mounted on the first heating element outer surface 21 of the heating element 20A. Note that, in the case where the boiling acceleration unit 60 is integrated with the heating element 20A or where the boiling acceleration unit 60 is previously mounted on the heating element 20A, the manufacturing method of the electronic device 100B is different from the manufacturing method of the electronic device 100 according to the first example embodiment in that the heating element 20A on which the boiling acceleration unit 60 is mounted is prepared, however, other processing is similar to the manufacturing method of the electronic device 100 according to the first example embodiment.

Next, the top surface (the surface on upper side of the page in FIG. 11) of the case 30 is attached to the case 30, thereby sealing the space enclosed by the inner part of the case 30, the heating element 20A,

and the connection unit 40. Then, the coolant COO is filled into the space enclosed by the inner part of the case 30, the heating element 20A, and the connection unit 40.

A method of filling the coolant COO into the space enclosed by the inner part of the case 30, the heating element 20A, and the connection unit 40 is as described in the description according to the first example embodiment.

The manufacturing method of the electronic device 100B is described as above.

Next, an operation of the electronic device 100B is described.

When the heating element 20A on the circuit board 10 operates, the heating element 20A generates heat. Herein, the boiling acceleration unit 60 provided on the first heating element outer surface 21 of the heating element 20A is in contact with the liquid-phase coolant LP-COO in the case 30. Accordingly, the liquid-phase coolant LP-COO being stored in the lower side of the case 30 in the vertical direction G boils on the boiling acceleration unit 60 by the heat of the heating element 20A, and turns to the gas-phase coolant GP-COO by the phase change. Thus, air bubbles of the gas-phase coolant GP-COO are generated. The heating element 20A is cooled by heat of vaporization (latent heat) generated by the phase change.

Further, the first heating element outer surface 21 of the heating element 20 is connected with the opening part 31 of the case 30 through the connection unit 40 formed by a heat conductive component. Accordingly, the heat of the heating element 20 is transferred to the case 30 through the connection unit 40. Consequently, the heating element 20 is cooled.

Further, the connection unit 40 is in contact with the liquid-phase coolant LP-COO in the case 30. Accordingly, the liquid-phase coolant LP-COO being stored in the lower side of the case 30 in the vertical direction G boils on the connection unit 40 by the heat of the heating element 20, and turns to the gas-phase coolant GP-COO by the phase change. Thus, air bubbles of the gas-phase coolant GP-COO are generated.

The gas-phase coolant GP-COO rises upward in the vertical direction G through the liquid-phase coolant LP-COO in the case 30, passes through a liquid surface of the liquid-phase coolant LP-COO, and further rises upward in the vertical direction G. When the gas-phase coolant GP-COO boiled by the heat of the heating element 20A is cooled by contact with an inner wall surface of the case 30, the gas-phase coolant GP-COO turns to the liquid-phase coolant LP-COO again by the phase change. The liquid-phase coolant LP-COO falls downward in the vertical direction G in the case 30, is stored on the circuit board 10 side, and is used again for cooling the heating element 20A.

The operation of the electronic device 100B is described above.

As described above, the electronic device 100B according to the second example embodiment further includes the boiling acceleration unit 60. The boiling acceleration unit 60 is provided on the first heating element outer surface 21 of the heating element H. The first heating element outer surface 21 of the heating element 20A is a surface opposite to the circuit board 10 side among the outer surfaces of the heating element 20A. The boiling acceleration unit 60 accelerates the phase change from the liquid-phase coolant LP-COO around the first heating element outer surface 21 to the gas-phase coolant GP-COO by the heat of the heating element 20A.

In this manner, by providing the boiling acceleration unit 60 on the first heating element outer surface 21 of the heating element 20A, the boiling nucleus (=the trigger for boiling) can be formed on the heating element 20A, and a superheating state (=a state in which boiling does not occur even when a boiling point is exceeded) can be suppressed. Accordingly, the heat of the heating element H is more efficiently transferred to the liquid-phase coolant LP-COO around the first heating element outer surface 21. Consequently, the liquid-phase coolant LP-COO around the first heating element outer surface 21 can turn to the gas-phase coolant GP-COO by the phase change more efficiently, compared with a case where the boiling acceleration unit 60 is not provided. In particular, the heat exchange area with the coolant COO can be increased by providing the boiling acceleration unit 60. Specifically, when the boiling acceleration unit 60 is not provided, the heat exchange area with the coolant COO is the area of the first heating element outer surface 21 of the heating element 20A. Herein, the surface area of the boiling acceleration unit 60 including the grooves and the porous body thereof is larger than the surface area of the first heating element outer surface 21 of the heating element 20A. Accordingly, when the boiling acceleration unit 60 is provided, the heat exchange area with the coolant COO becomes larger, compared with the case where the boiling acceleration unit 60 is not provided. Consequently, the heat of the heating element H can be transferred more efficiently to the coolant COO.

Further, in the electronic device 100B according to the second example embodiment, the boiling acceleration unit 60 is the grooves or the porous body formed on the first heating element outer surface 21. Thus, the boiling acceleration unit 60 can be formed easily.

Note that, according to the second example embodiment, an aspect in which the boiling acceleration unit 60 is added to the electronic device 100B is described, however, the boiling acceleration unit 60 can also be added to the electronic devices 100 to 100A.

### First Modification Example of Second Example Embodiment

A configuration of an electronic device 100C being a first modification example of the electronic device according to the second example embodiment of the present invention is described based on the drawings.

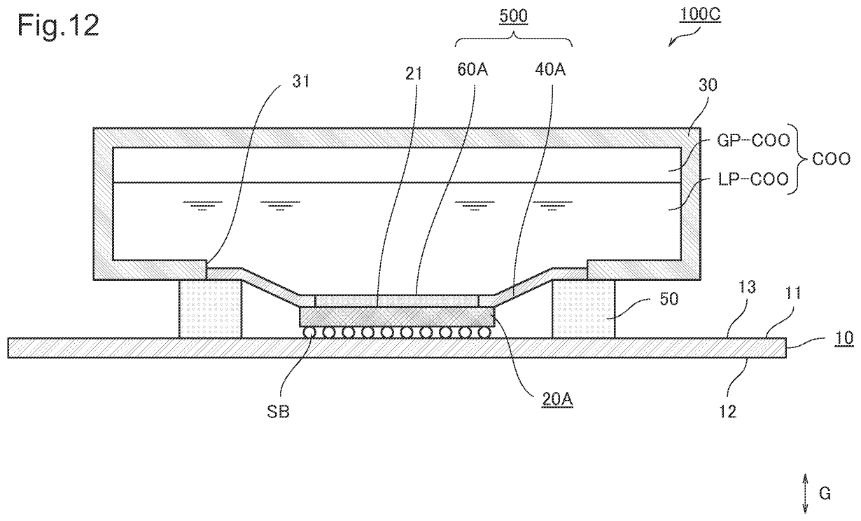

FIG. 12 is a cross-sectional view of the configuration of the electronic device 100C. FIG. 12 is the cross-sectional view associated with FIG. 1. Note that the vertical direction G is illustrated in FIG. 12. Further, in FIG. 12, a component equivalent to each component illustrated in FIGS. 1 to 11 is indicated with a same reference sign as the reference sign illustrated in FIGS. 1 to 11.

Referring to FIG. 12, the electronic device 100C includes a circuit board 10, a heating element 20A, a case 30, a connection unit 40A, a holding unit 50, and a boiling acceleration unit 60A. The connection unit 40A and the boiling acceleration unit 60A are formed in a metal plate 500. The electronic device 100C can be attached to a housing rack 200 similarly to the electronic device 100. Note that the electronic device 100C can be used as an electronic module to be incorporated in a communication device, a server, and the like, for example.

Herein, comparison is made between the electronic device 100C and the electronic device 100B. In the electronic device 100B, the boiling acceleration unit 60 and the connection unit 40 are formed separately as illustrated in FIG. 11. In contrast, in the electronic device 100C, the metal plate 500 is configured by forming in such a way that the boiling acceleration unit 60A and the connection unit 40A are integrated as illustrated in FIG. 12. In this respect, the electronic device 100B and the electronic device 100C are different from each other.

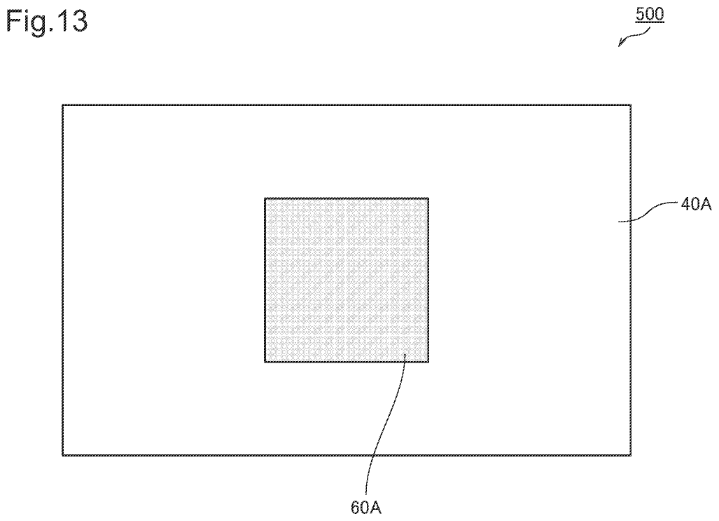

FIG. 13 is a plan view of a configuration of the metal plate 500. As illustrated in FIG. 13, the boiling acceleration unit 60A and the connection unit 40A are formed in the metal plate 500. An outer shape of the metal plate 500 is, for example, associated with a shape of an opening part 31. Since a first heating element top surface 21 of the heating element 20A and the opening part 31 have different heights in the vertical direction G, the outer shape of the metal plate 500 is usually set one size larger than the shape of the opening part 31.

Further, the boiling acceleration unit 60A is placed at a center part of the metal plate 500 and the connection unit 40A is placed at an outer peripheral part (area surrounding the center part) of the metal plate 500.

The connection unit 40A is formed by the outer peripheral part of the metal plate 500. Thus, the outer peripheral part of the metal plate 500 serves as the connection unit 40A. For this reason, the metal plate 500 is formed by a heat conductivity member, similarly to the connection unit 40 according to the first example embodiment. As the material for the metal plate 500, copper, copper alloy, silver, silver alloy, gold, gold alloy, aluminum, aluminum alloy or the like is used as the heat conductivity member, for example, similarly to the material of the connection unit 40. For the metal plate 500, a plate or foil (equal to or less than 0.21 mm thick) is used.

The boiling acceleration unit 60A is configured of a plurality of holes formed in the center part of the metal plate 500. Note that the plurality of holes may be arranged in a reticulated pattern. Note that a diameter of the plurality of holes may be, for example, 100 to 200 μm.

The configuration of the electronic device 100C is described as above.

Next, a manufacturing method of the electronic device 100C is described.

First, the circuit board 10 on which the heating element 20A is mounted is prepared. Next, the holding unit 50 is mounted on a first main surface 11 of the circuit board 10. The case 30 is fixed on the holding unit 50. At this time, a top surface (a surface on upper side of the page in FIG. 12) of the case 30 is formed in such a way as to be removable.

Next, in a state where the top surface of the case 30 is removed, the metal plate 500 is mounted on the opening part 31 of the case 30 and the first heating element outer surface 21 of the heating element 20A. Specifically, the boiling acceleration unit 60A in the metal plate 500 is mounted on the first heating element outer surface 21 of the heating element 20A by fixing with an adhesive or a screw. Further, by fixing with an adhesive or a screw, one end part of the connection unit 40A in the metal plate 500 is mounted on an outer peripheral part of the first heating element outer surface 21, and another end part of the connection unit 40A in the metal plate 500 is attached to the opening part 31 of the case 30. Thus, the opening part 31 of the case 30 and the heating element 20A are connected by the connection unit 40A in the metal plate 500. Consequently, a space enclosed by an inner part of the case 30, the heating element 20A, and the connection unit 40A can be formed.

Next, the top surface (the surface on upper side of the page in FIG. 12) of the case 30 is attached to the case 30, thereby sealing the space enclosed by the inner part of the case 30, the heating element 20A, and the connection unit 40A. Then, the coolant COO is filled into the space enclosed by the inner part of the case 30, the heating element 20A, and the connection unit 40A.

A method of filling the coolant COO into the space enclosed by the inner part of the case 30, the heating element 20A, and the connection unit 40A is as described in the description according to the first example embodiment.

The manufacturing method of the electronic device 100C is described as above.

Next, an operation of the electronic device 100C is described.

When the heating element 20A on the circuit board 10 operates, the heating element 20A generates heat. Herein, the boiling acceleration unit 60A provided on the first heating element outer surface 21 of the heating element 20A is in contact with the liquid-phase coolant LP-COO in the case 30. Accordingly, the liquid-phase coolant LP-COO being stored in the lower side of the case 30 in the vertical direction G boils on the boiling acceleration unit 60A by the heat of the heating element 20A, and turns to the gas-phase coolant GP-COO by the phase change. Thus, air bubbles of the gas-phase coolant GP-COO are generated. The heating element 20A is cooled by heat of vaporization (latent heat) generated by the phase change.

Further, the first heating element outer surface 21 of the heating element 20A is connected with the opening part 31 of the case 30 through the connection unit 40A formed in the metal plate 500. Accordingly, the heat of the heating element 20A is transferred to the case 30 through the connection unit 40A. Consequently, the heating element 20A is cooled.

Further, the connection unit 40A is in contact with the liquid-phase coolant LP-COO in the case 30. Accordingly, the liquid-phase coolant LP-COO being stored in the lower side of the case 30 in the vertical direction G boils on the connection unit 40A by the heat of the heating element 20A, and turns to the gas-phase coolant GP-COO by the phase change. Thus, air bubbles of the gas-phase coolant GP-COO are generated.

The gas-phase coolant GP-COO rises upward in the vertical direction G through the liquid-phase coolant LP-COO in the case 30, passes through a liquid surface of the liquid-phase coolant LP-COO, and further rises upward in the vertical direction G. When the gas-phase coolant GP-COO boiled by the heat of the heating element 20A is cooled by contact with an inner wall surface of the case 30, the gas-phase coolant GP-COO turns to the liquid-phase coolant LP-COO again by the phase change. The liquid-phase coolant LP-COO falls downward in the vertical direction G in the case 30, is stored on the circuit board 10 side, and is used again for cooling the heating element 20A.

The operation of the electronic device 100C is described above.

As described above, in the electronic device 100C being the first modification example of the electronic device according to the second example embodiment of the present invention, the connection unit 40A and the boiling acceleration unit 60A are formed integrally.

Thus, two functions of the connection unit 40A and the boiling acceleration unit 60A can be integrated into a single component. Consequently, the number of components can be reduced. Further, since the number of components is reduced, assembly of the electronic device 100C can be made easier.

Further, in the electronic device 100C being the first modification example of the electronic device according to the second example embodiment of the present invention, the boiling acceleration unit 60A is configured of a plurality of holes formed in the center part of the metal plate 500. Further, the connection unit 40A is configured of the outer peripheral part that surrounds the center part of the metal plate 500.

Thus, the two functions of the connection unit 40A and the boiling acceleration unit 60A can be included in the metal plate 500. Consequently, the number of components can be reduced. Further, since the number of components is reduced, assembly of the electronic device 100C can be made easier.

### Third Example Embodiment

A configuration of an electronic device 100D according to a third example embodiment of the present invention is described based on the drawings.

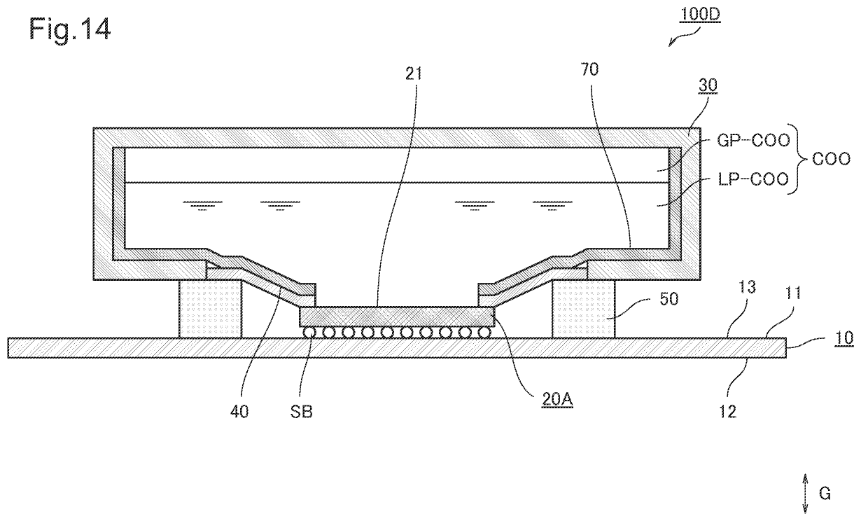

FIG. 14 is a cross-sectional view of the configuration of the electronic device 100D. FIG. 14 is the cross-sectional view associated with FIG. 1. Note that a vertical direction G is illustrated in FIG. 14. Further, in FIG. 14, a component equivalent to each component illustrated in FIGS. 1 to 13 is indicated with a same reference sign as the reference sign illustrated in FIGS. 1 to 13.

Referring to FIG. 14, the electronic device 100D includes a circuit board 10, a heating element 20A, a case 30, a connection unit 40, a holding unit 50, and a coolant flow path 70. The electronic device 100D can be attached to a housing rack 200 similarly to the electronic device 100. Note that the electronic device 100D can be used as an electronic module to be incorporated in a communication device, a server, and the like, for example.

Herein, comparison is made between the electronic device 100D and the electronic device 100A. As illustrated in FIG. 14, the electronic device 100D is different from the electronic device 100A in that the electronic device 100D includes the coolant flow path 70.

Referring to FIG. 14, the coolant flow path 70 is provided on an inner surface of the case 30 from a side of an opening part 31 to a surface upper than a liquid surface of a liquid-phase coolant LP-COO in the vertical direction G, and on a surface that faces the inner side of the case 30 among surfaces of the connection unit 40. Specifically, the coolant flow path 70 is formed on side surfaces (left-side surface and right-side surface on the page in FIG. 14) and a bottom surface (bottom-side surface on the page in FIG. 14) of the inner surface of the case 30, and on the surface that faces the inner side of the case 30 among the surfaces of the connection unit 40.

A lower end of the coolant flow path 70 is in proximity to the heating element 20A. An upper end of the coolant flow path 70 is set to a part upper than a liquid surface of a liquid-phase coolant LP-COO in the vertical direction G, when the amount of the liquid-phase coolant LP-COO in the case 30 is the smallest. The case where the amount of the liquid-phase coolant LP-COO in the case 30 is the smallest is a state in which the most amount of the liquid-phase coolant LP-COO undergoes a phase change and the amount of the gas-phase coolant GP-COO is the largest in the whole coolant COO. Thus, in the example of FIG. 14, the upper end of the coolant flow path 70 is set on the inner side surface of the case 30, but the upper end of the coolant flow path 70 may be set on a bottom side of the case 30 or on a connection unit 40 side.

Herein, the coolant flow path 70 is formed in such a way that the liquid-phase coolant LP-COO in the case 30 flows toward the heating element 20A. The coolant flow path 70 is formed by a porous body or fine grooves that lead the liquid-phase coolant LP-COO to the heating element 20A by a capillary phenomenon, for example. Note that the capillary phenomenon is a physical phenomenon in which a liquid inside a thin tubular object (capillary tube) rises (or falls in some cases) inside the tube. Note that the porous body is formed with a plurality of micropores as described above.

The porous body may be configured of a sintered body or a mesh, for example, similarly to the boiling acceleration unit 40 described above.

The fine grooves are formed in such a way as to go outward with the heating element 20A as a center. The grooves can be formed by cutting the inner surface of the case 30 or by applying a member with fine protrusions to the inner surface of the case 30.

Note that the porous body and the fine grooves may be formed on the entire inner surface or a partial inner surface of the case 30.

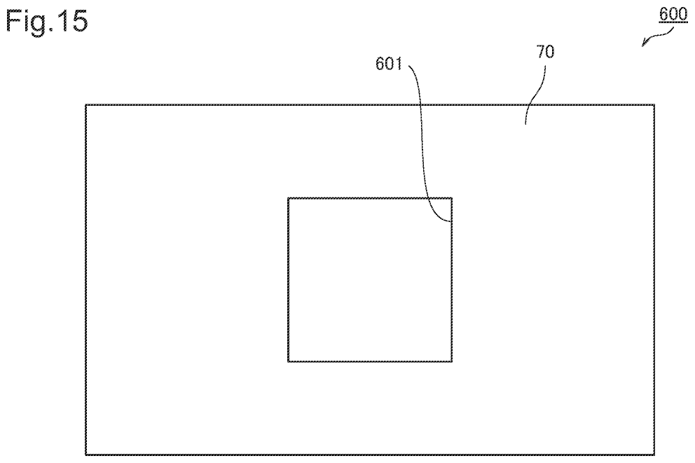

Herein, the coolant flow path 70 can be configured using a reticulated sheet 600. The reticulated sheet 600 may be configured of a mesh. FIG. 15 is a plan view of the configuration of the reticulated sheet 600 as one example of a member configuring the coolant flow path 70. As illustrated in FIG. 15, the reticulated sheet 600 can include a function of the coolant flow path 70. The reticulated sheet 600 includes the opening part 601. The opening part 601 is formed in such a way as to be sized according to an outer shape of the heating element 20A.

Herein, an outer shape of the reticulated sheet 600 is formed in accordance with a size and a shape of the bottom surface of the case 30. In this case, the coolant flow path 70 to be mounted on the inner side surface of the case 30 needs to be provided separately. However, the outer shape of the reticulated sheet 600 may be formed in accordance with not only the size and the shape of the inner bottom surface of the case 30 but also a size and a shape of the inner side surface of the case 30. In this case, the coolant flow path 70 can be provided on the inner bottom surface and the inner side surface of the case 30 by preparing only one reticulated sheet.

The reticulated sheet 600 may be combined with the connection unit 40. In this case, the metal plate configuring the connection unit 40 is stuck to the reticulated sheet 600.

The configuration of the electronic device 100D is described as above.

Next, a manufacturing method of the electronic device 100D is described.

First, the circuit board 10 on which the heating element 20A is mounted is prepared. Next, the holding unit 50 is mounted on a first main surface 11 of the circuit board 10. The case 30 is fixed on the holding unit 50. At this time, a top surface (a surface on upper side of the page in FIG. 12) of the case 30 is formed in such a way as to be removable.

Next, in a state where the top surface of the case 30 is removed, the connection unit 40 is mounted on the opening part 31 of the case 30 and a first heating element outer surface 21 of the heating element 20A. Specifically, one end part of the connection unit 40 is mounted on the first heating element outer surface 21 of the heating element 20A by fixing with an adhesive or a screw. Further, another end part of the connection unit 40 is mounted on the opening part 31 of the case 30 by fixing with an adhesive or a screw. Accordingly, the opening part 31 of the case 30 and the heating element 20A are connected by the connection unit 40. Consequently, a space enclosed by an inner part of the case 30, the heating element 20A, and the connection unit 40 can be formed.

Next, the reticulated sheet 600 is mounted on the inner bottom surface of the case 30 and the connection unit 40. Further, the coolant flow path 70 is also provided on the inner side surface of the case 30. At this time, the inner side surface of the case 30 may be mounted with a member integral with the reticulated sheet 600 or a member separate from the reticulated sheet 600.

Next, the top surface (the surface on upper side of the page in FIG. 14) of the case 30 is attached to the case 30, thereby sealing the space enclosed by the inner part of the case 30, the heating element 20A, and the connection unit 40. Then, the coolant COO is filled into the space enclosed by the inner part of the case 30, the heating element 20A, and the connection unit 40A.

A method of filling the coolant COO into the space enclosed by the inner part of the case 30, the heating element 20A, and the connection unit 40A is as described in the description according to the first example embodiment.

The manufacturing method of the electronic device 100D is described as above.

Next, an operation of the electronic device 100D is described.

When power is supplied to the heating element 20A on the circuit board 10, the heating element 20A generates heat.

Herein, a center part of the first heating element outer surface 21 of the heating element 20A is in contact with the liquid-phase coolant LP-COO in the case 30. Accordingly, the liquid-phase coolant LP-COO being stored in the lower side of the case 30 in the vertical direction G boils on the first heating element outer surface 21 of the heating element 20A by the heat of the heating element 20A, and turns to the gas-phase coolant GP-COO by the phase change. Thus, air bubbles of the gas-phase coolant GP-COO are generated. The heating element 20A is cooled by heat of vaporization (latent heat) generated by the phase change.

Further, the first heating element outer surface 21 of the heating element 20A is connected with the opening part 31 of the case 30 through the connection unit 40. Accordingly, the heat of the heating element 20A is transferred to the case 30 through the connection unit 40. Consequently, the heating element 20A is cooled.

The gas-phase coolant GP-COO rises upward in the vertical direction G through the liquid-phase coolant LP-COO in the case 30, passes through a liquid surface of the liquid-phase coolant LP-COO, and further rises upward in the vertical direction G. When the gas-phase coolant GP-COO boiled by the heat of the heating element 20A is cooled by contact with an inner wall surface of the case 30, the gas-phase coolant GP-COO turns to the liquid-phase coolant LP-COO again by the phase change. The liquid-phase coolant LP-COO falls downward in the vertical direction G in the case 30, is stored on the circuit board 10 side, and is used again for cooling the heating element 20A.

At this time, the liquid-phase coolant LP-COO flows through the coolant flow path 70 toward the heating element 20A. In particular, the liquid-phase coolant LP-COO is led to the heating element 20A by the capillary phenomenon in the coolant flow path 70.

Then, the liquid-phase coolant LP-COO being stored in the lower side of the case 30 in the vertical direction G boils again on the first heating element outer surface 21 of the heating element 20A by the heat of the heating element 20A, and turns to the gas-phase coolant GP-COO by the phase change. Thereafter, the operation described above is repeated, and thus, the coolant COO circulates within the case 30.

The operation of the electronic device 100D is described above.

As described above, the electronic device 100D according to the third example embodiment further includes the coolant flow path 70. The coolant flow path 70 is provided on the inner surface of the case 30 from the side of the opening part 31 to the surface upper than the liquid surface of the liquid-phase coolant LP-COO in the vertical direction G, and on the surface that faces the inner side of the case 30 among the surfaces of the connection unit 40. The coolant flow path 70 is formed in such a way that the liquid-phase coolant LP-COO flows toward the heating element 20A.

In this manner, the coolant flow path 70 is provided on the inner surface of the case 30 from the side of the opening part 31 to the surface upper than the liquid surface of the liquid-phase coolant LP-COO in the vertical direction G, and on the surface that faces the inner side of the case 30 among the surfaces of the connection unit 40. The coolant flow path 70 is formed in such a way that the liquid-phase coolant LP-COO flows toward the heating element 20A. Accordingly, the liquid-phase coolant LP-COO being generated in the upper part of the case 30 in the vertical direction G flows toward the heating element 20A through the coolant flow path 70. Thus, the liquid-phase coolant LP-COO can be supplied to the heating element 20A more quickly and smoothly. Consequently, the heat of the heating element 20A can be cooled more efficiently, compared with a case where the coolant flow path 70 is not provided.

Herein, comparison with the case where the coolant flow path 70 is not provided is made. When the coolant flow path 70 is not provided, a flow path of the liquid-phase coolant LP-COO toward the heating element 20A and a flow path of the gas-phase coolant GP-COO away from the heating element 20A are not divided, and thus, a collision between the gas-phase coolant GP-COO and the liquid-phase coolant LP-COO occurs inside the case 30. Consequently, a situation where the coolant COO is not smoothly circulated inside the case 30 may occur.

In particular, when a heating value of the heating element 20A increases, an amount of vapor (gas-phase coolant GP-COO) to be generated increases. In this case, the heating element 20A is completely covered with the gas-phase coolant GP-COO, and it may happen that the liquid-phase coolant LP-COO is not supplied to the heating element 20A. When the liquid-phase coolant LP-COO is not supplied to the heating element 20A, the coolant COO does not undergo the phase change, and thus, the heating element 20A cannot be cooled.

In contrast, when the coolant flow path 70 is provided, a dedicated flow path for the liquid-phase coolant LP-COO is set. Thus, the flow path for the gas-phase coolant GP-COO and the flow path for the liquid-phase coolant LP-COO can be provided separately. Consequently, occurrence of the collision between the gas-phase coolant GP-COO and the liquid-phase coolant LP-COO can be avoided. In this way, the electronic device 100D can avoid the occurrence of the collision between the gas-phase coolant GP-COO and the liquid-phase coolant LP-COO, and thus, the liquid phase coolant LP-COO can be supplied more quickly and smoothly to the heating element 20A and the coolant COO can be circulated smoothly, compared with the case where the coolant flow path 70 is not provided. Therefore, the electronic device 100D is able to cool the heat of the heating element 20A more efficiently, compared with the case where the coolant flow path 70 is not provided.

Further, in the electronic device 100D according to the third example embodiment, the coolant flow path 70 leads the liquid-phase coolant LP-COO by the capillary phenomenon. In this manner, the electronic device 100D is able to lead the liquid-phase coolant LP-COO to the heating element 20A by the capillary phenomenon, and thus, the liquid-phase coolant LP-COO can be supplied to the heating element 20A more quickly and smoothly. Consequently, the heat of the heating element 20A can be cooled more efficiently, compared with the case where the coolant flow path 70 is not provided. Further, the coolant flow path 70 leads the liquid-phase coolant LP-COO by the capillary phenomenon, and thus, the liquid-phase coolant LP-COO can be led to the heating element 20A against gravity even when the electronic device 100D is placed upside down or the electronic device 100D is placed vertically in FIG. 14. The case where the electronic device 100D is placed vertically is, for example, a case where the first main surface 11 of the circuit board 10 is placed parallel to the vertical direction G.

Further, in the electronic device 100D according to the third example embodiment, the coolant flow path 70 may be configured in such a way that the reticulated sheet 600 is provided on the inner surface of the case 30 from the side of the opening part 31 to the surface upper than the liquid surface of the liquid-phase coolant LP-COO in the vertical direction G, and on the surface that faces the inner side of the case 30 among the surfaces of the connection unit 40. In this manner, by using the reticulated sheet 600 as a member, the coolant flow path 70 that causes the capillary phenomenon can be formed easily. As the material of the reticulated sheet 600, copper, copper alloy, silver, silver alloy, gold, gold alloy, aluminum, aluminum alloy, or the like is used, for example.

Further, in the electronic device 100D according to the third example embodiment, the coolant flow path 70 is formed of the grooves or the porous body. Thus, the coolant flow path 90 that causes the capillary phenomenon can be formed easily.

Note that, according to the third example embodiment, an aspect in which the coolant flow path 70 is added to the electronic device 100D is described, however, the coolant flow path 70 can also be added to the electronic devices 100A to 100C.

### Fourth Example Embodiment

A configuration of an electronic device 100E according to a fourth example embodiment of the present invention is described based on the drawings.

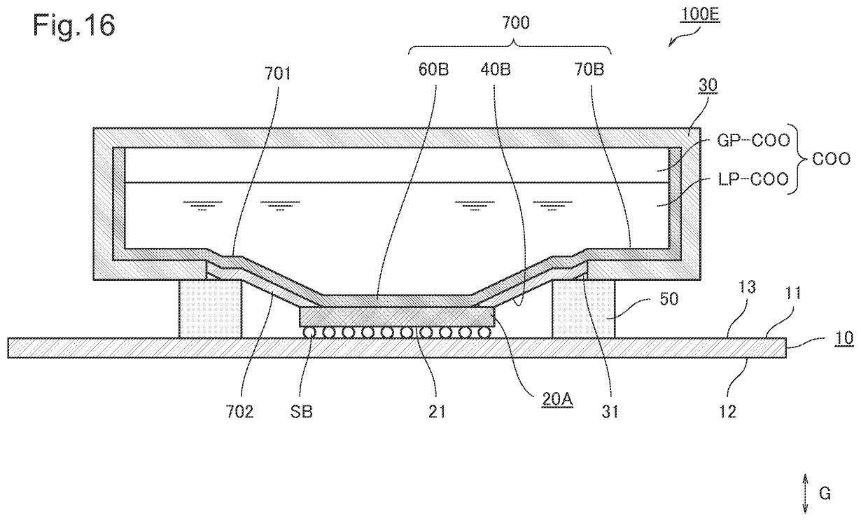

FIG. 16 is a cross-sectional view of the configuration of the electronic device 100E. FIG. 16 is the cross-sectional view associated with FIG. 1. Note that a vertical direction G is illustrated in FIG. 16. Further, in FIG. 16, a component equivalent to each component illustrated in FIGS. 1 to 15 is indicated with a same reference sign as the reference sign illustrated in FIGS. 1 to 15.

Referring to FIG. 16, the electronic device 100E includes a circuit board 10, a heating element 20A, a case 30, a connection unit 40B, a holding unit 50, a boiling acceleration unit 60B, and a coolant flow path 70B. The electronic device 100E can be attached to a housing rack 200 similarly to the electronic device 100. Note that the electronic device 100E can be used as an electronic module to be incorporated in a communication device, a server, and the like, for example.

Herein, comparison is made between the electronic device 100E and the electronic device 100D. As illustrated in FIG. 16, the electronic device 100E is different from the electronic device 100D in that the electronic device 100E further includes the boiling acceleration unit 60B in addition to the coolant flow path 70B.

Herein, in the electronic device 100E, the connection unit 40B, the boiling acceleration unit 60B and the coolant flow path 70B are formed of a laminated plate 700.

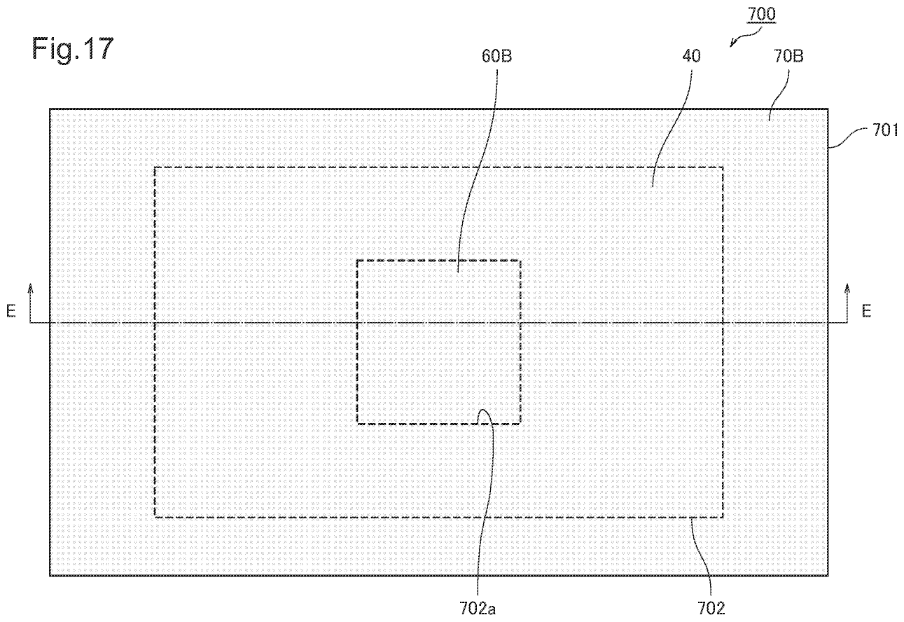

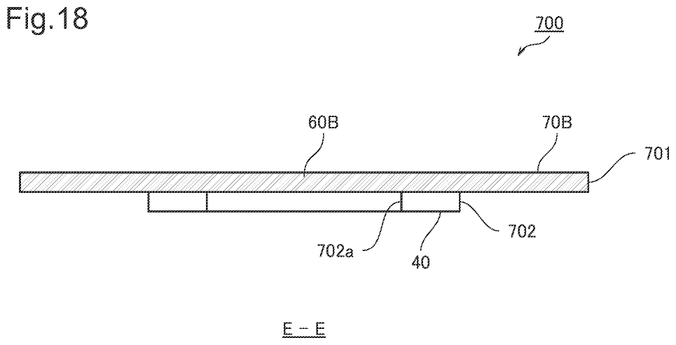

FIG. 17 is a plan view of a configuration of the laminated plate 700 as one example of a member configuring the connection unit 40B, the boiling acceleration unit 60B, and the coolant flow path 70B. FIG. 18 is a cross-sectional view of the configuration of the laminated plate 700 and illustrates a section at an E-E cutting plane in FIG. 17.

As illustrated in FIGS. 17 and 18, the laminated plate 700 is configured of two sheets. Specifically, one of the two sheets is, for example, a reticulated sheet 701, forming the boiling acceleration unit 60B and the coolant flow path 70B. The reticulated sheet 701 may be a mesh. Another sheet of the two sheets is, for example, a metal sheet 702, forming the connection unit 40B. The reticulated sheet 701 of the laminated plate 700 is placed on an upper side in the vertical direction G, compared with the metal sheet 702. In other words, the metal sheet 702 is placed closer to the circuit board 10, compared with the reticulated sheet 701.

Herein, an outer shape of the reticulated sheet 701 is formed in accordance with a size and a shape of the bottom surface of the case 30. In this case, the coolant flow path 70 to be mounted on an inner side surface of the case 30 needs to be provided separately. However, the outer shape of the reticulated sheet 701 may be formed in accordance with not only the size and the shape of the inner bottom surface of the case 30 but also a size and a shape of the inner side surface of the case 30. In this case, the coolant flow path 70 can be provided on the inner bottom surface and the inner side surface of the case 30 by preparing only one reticulated sheet.

Herein, an outer shape of the metal sheet 702 is associated with a size of an opening part 31 of the case 30. Further, the metal sheet 702 includes an opening part 702a. The opening part 702a is associated with an outer shape of a first heating element outer surface 21 of the heating element 20A. Specifically, a dimension at each part of the metal sheet 702 is adjusted in such a way that the metal sheet 702 as the connection unit 40B can connect between the heating element 20A and the opening part 31 when the laminated plate 700 is mounted. As the material of the metal sheet 702, copper, copper alloy, silver, silver alloy, gold, gold alloy, aluminum, aluminum alloy, or the like is used as a heat conductive member, for example, similarly to the material of the connection unit 40. For the metal sheet 702, a plate or foil (equal to or less than 0.21 mm thick) is used.

Note that the laminated plate 700 is introduced herein as one example of the member configuring the connection unit 40B, the boiling acceleration unit 60B, and the coolant flow path 70B, however, the laminated plate 700 may be configured of separated sheets as the reticulated sheet 701 and the metal sheet 702, without putting the two sheets together.

Functions of the connection unit 40B, the boiling acceleration unit 60B, and the coolant flow path 70B are similar to the above-described connection unit 40, the boiling acceleration unit 60, and the coolant flow path 70.

The configuration of the electronic device 100E is described as above.

Next, a manufacturing method of the electronic device 100E is described.

First, the circuit board 10 on which the heating element 20A is mounted is prepared. Next, the holding unit 50 is mounted on a first main surface 11 of the circuit board 10. The case 30 is fixed on the holding unit 50. At this time, a top surface (a surface on upper side of the page in FIG. 16) of the case 30 is formed in such a way as to be removable.

Next, in a state where the top surface of the case 30 is removed, the laminated plate 700 is mounted on a bottom surface side of the case 30 in such a way that the metal sheet 702 comes to lower side. In other words, the metal sheet 702 is placed closer to the circuit board 10, compared with the reticulated sheet 701.

Specifically, the connection unit 40B configured of the metal sheet 702 is mounted on the opening part 31 of the case 30 and the first heating element outer surface 21 of the heating element 20A. In other words, one end part of the connection unit 40B is mounted on the first heating element outer surface 21 of the heating element 20A by fixing with an adhesive or a screw. Further, another end part of the connection unit 40B is mounted on the opening part 31 of the case 30 by fixing with an adhesive or a screw. Thus, the opening part 31 of the case 30 and the heating element 20A are connected by the connection unit 40B. Consequently, a space enclosed by an inner part of the case 30, the heating element 20A, and the connection unit 40B can be formed.

Next, the boiling acceleration unit 60B configured of the reticulated sheet 701 is mounted on the first heating element outer surface 21 of the heating element 20A. At the same time, the coolant flow path 70B configured of the reticulated sheet 701 is mounted on the inner bottom surface of the case 30 and the inner surface of the connection unit 40B. Further, the coolant flow path 70B is also provided on an inner side surface of the case 30. At this time, the inner side surface of the case 30 may be mounted with a member integral with the reticulated sheet 701 or a member separate from the reticulated sheet 701.

Next, the top surface (the surface on upper side of the page in FIG. 16) of the case 30 is attached to the case 30, thereby sealing the space enclosed by the inner part of the case 30, the heating element 20A, and the connection unit 40B. Then, the coolant COO is filled into the space enclosed by the inner part of the case 30, the heating element 20A, and the connection unit 40B.

A method of filling the coolant COO into the space enclosed by the inner part of the case 30, the heating element 20A, and the connection unit 40B is as described in the description according to the first example embodiment.

The manufacturing method of the electronic device 100E is described as above.

As described above, in the electronic device 100E according to the fourth example embodiment, the boiling acceleration unit 60B and the coolant flow path 70B are formed integrally.

Thus, by forming the boiling acceleration unit 60B and the coolant flow path 70B integrally, the number of components can be reduced, compared with a case where the boiling acceleration unit 60B and the coolant flow path 70B are formed separately. Further, since the number of components is reduced, assembly of the electronic device 100E can be made easier.

Further, in the electronic device 100E according to the fourth example embodiment, the boiling acceleration unit 60B and the coolant flow path 70B are configured in such a way that the reticulated sheet 701 is mounted on the inner surface of the case 30 from the side of the opening part 31 to the surface upper than the liquid surface of the liquid-phase coolant LP-COO in the vertical direction G, on the surface that faces the inner side of the case 30 among surfaces of the connection unit 40B, and on the first heating element outer surface 21. Thus, by using the reticulated sheet 701, the boiling acceleration unit 60B and the coolant flow path 70B can be provided easily.

### Fifth Example Embodiment

A configuration of an electronic device 100F according to a fifth example embodiment of the present invention is described based on the drawings.

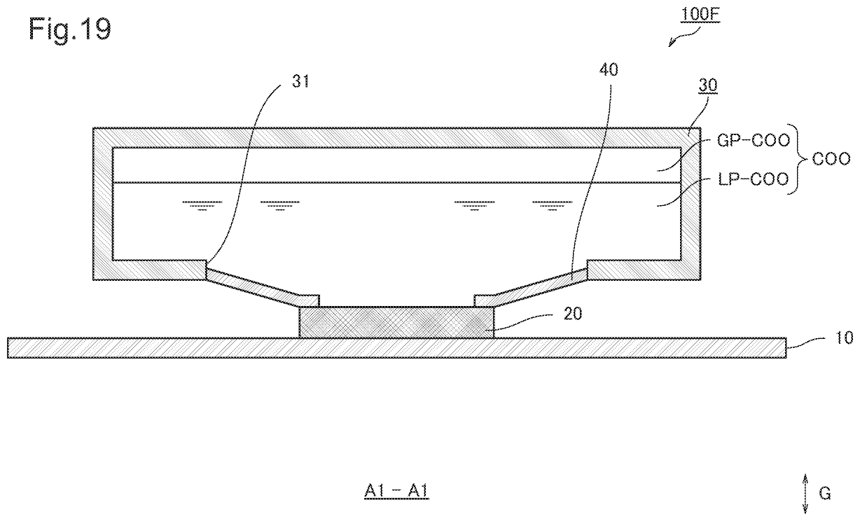

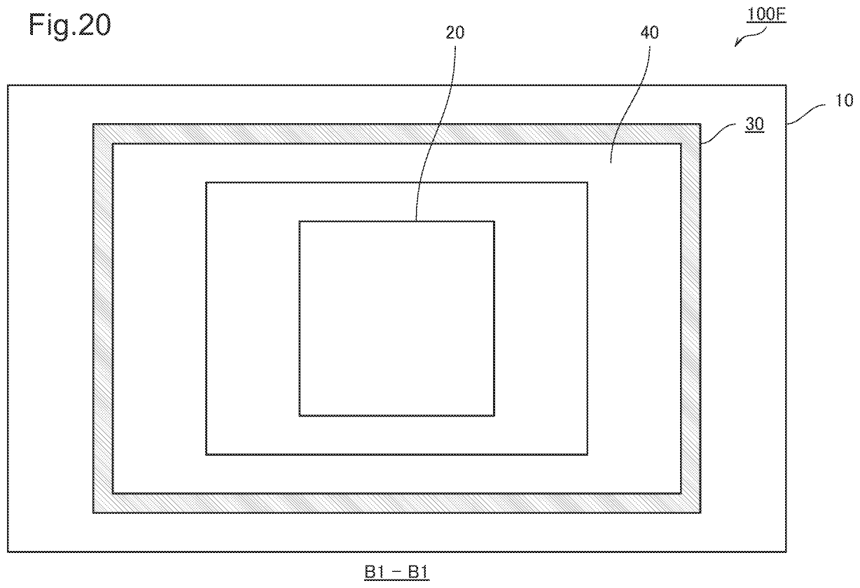

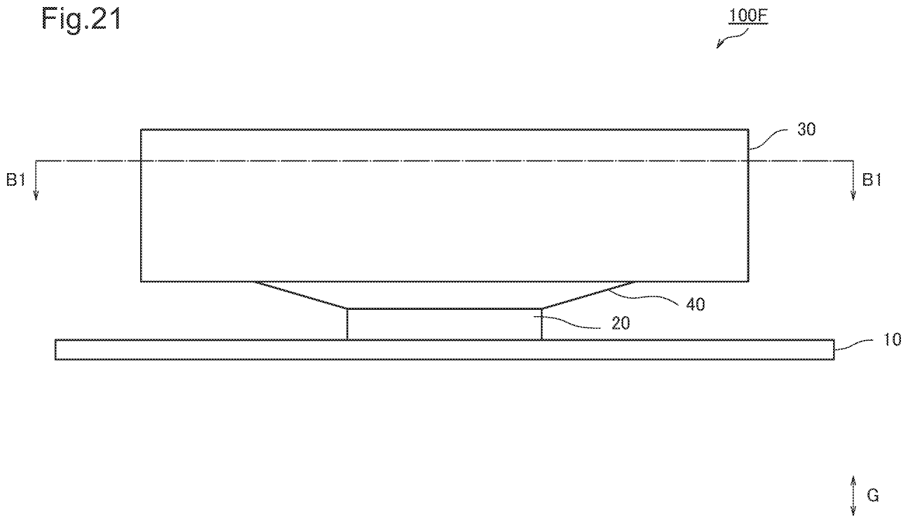

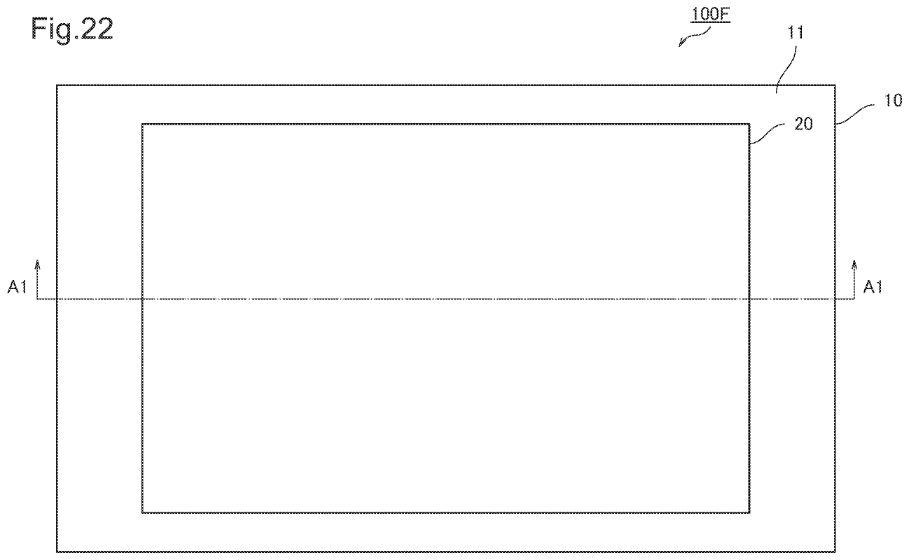

FIG. 19 is a cross-sectional view of a configuration of an electronic device 100F and illustrates a section at an A1-A1 cutting plane in FIG. 22. FIG. 20 is a cross-sectional view of the configuration of the electronic device 100F and illustrates a section at a B1-B1 cutting plane in FIG. 3. FIG. 21 is a side view of the configuration of the electronic device 100F. FIG. 22 is a top view of the configuration of the electronic device 100F. Note that a vertical direction G is illustrated in FIGS. 19 and 22.

Referring to FIGS. 19 to 22, the electronic device 100F includes a circuit board 10, a case 30, and a connection unit 40. Note that the electronic device 100F can be used as an electronic module to be incorporated in a communication device, a server, and the like, for example.

A heating element 20 is mounted on at least one surface of the circuit board 10. The circuit board 10 is, for example, a printed wiring board. The heating element 20 is a component that generates heat during operation such as a central processing device CPU and an integrated circuit MCM.

As illustrated in FIG. 19, the case 30 houses a coolant COO. An opening part 31 is formed, among surfaces constituting the case 30, on a surface facing a top surface (surface on upper side of the page in FIG. 19) of the circuit board 10. The opening part 31 is usually provided at a position facing the heating element 20.

The connection unit 40 connects the opening part 31 of the case 30 and the heating element 20, thereby sealing the coolant COO. The connection unit 40 is placed between the case 30 and the heating element 20, and connects the case 30 and the heating element 20. A thickness of the connection unit 40 is equal to or less than 0.21 mm.

Hydro fluorocarbon HFC, hydro fluoroether HFE, and the like can be used as the coolant COO, for example.

The coolant COO is contained in a sealed state in a space where the opening part 31 of the case 30 is sealed by the heating element 20 and the connection unit 40. Accordingly, vacuum evacuation is performed after injecting a liquid-phase coolant LP-COO into the space sealed by an inner part of the case 30, the heating element 20, and the connection unit 40, and thus a saturated vapor pressure of the coolant can be always maintained in the sealed space. Note that a method of filling the coolant COO into the space sealed by the inner part of the case 30, the heating element 20, and the connection unit 40 is described later in detail in a description about a manufacturing method of the electronic device 100F.

The configuration of the electronic device 100F is described as above.

Next, a manufacturing method of the electronic device 100F is described.

First, the circuit board 10 on which the heating element 20 is mounted is prepared. Next, the connection unit 40 connects the opening part 31 of the case 30 and the heating element 20 by fixing with an adhesive or a screw, for example. Accordingly, the heating element 20 and the opening part 31 of the case 30 are connected by the connection unit 40. Consequently, the sealed space is formed by the inner part of the case 30, the heating element 20, and the connection unit 40.

Next, the coolant COO is filled in the space enclosed by the case 30, the heating element 20, and the connection unit 40.

A method of filling the coolant COO into the space enclosed by the case 30, the heating element 20, and the connection unit 40 is similar to the description according to the first example embodiment.

The manufacturing method of the electronic device 100F is described as above.

Next, an operation of the electronic device 100F is described.

When the electronic device 100F is activated, power is supplied to the heating element 20 on the circuit board 10. Thus, the heating element 20 generates heat.

Herein, a top surface of the heating element 20 is in contact with the liquid-phase coolant LP-COO in the case 30. Accordingly, the liquid-phase coolant LP-COO being stored in a lower side of the case 30 in the vertical direction G boils on a top surface of the heating element 20 by the heat of the heating element 20, and turns to a gas-phase coolant GP-COO by a phase change. Thus, air bubbles of the gas-phase coolant GP-COO are generated. The heating element 20 is cooled by heat of vaporization (latent heat) generated by the phase change.

The gas-phase coolant GP-COO rises upward in the vertical direction G through the liquid-phase coolant LP-COO in the case 30 through the connection unit 40, passes through a liquid surface of the liquid-phase coolant LP-COO, and further rises upward in the vertical direction G. When the gas-phase coolant GP-COO boiled by the heat of the heating element 20 is cooled by contact with an inner wall surface of the case 30, the gas-phase coolant GP-COO turns to the liquid-phase coolant LP-COO again by the phase change. The liquid-phase coolant LP-COO falls downward in the vertical direction G in the case 30, is stored on the circuit board 10 side, and is used again for cooling the heating element 20.

The operation of the electronic device 100F is described above.

As described above, the electronic device 100F according to the fifth example embodiment of the present invention includes the circuit board 10, the case 30, and the connection unit 40. The heating element 20 is mounted on a first main surface 11 of the circuit board 10. The case 30 includes the opening part 31 and houses the coolant COO. The opening part 31 is formed on the surface facing the heating element 20 among the surfaces constituting the case 30. The connection unit 40 is formed by a heat conductive member. The connection unit 40 connects the opening part 31 and the heating element 20, thereby sealing the coolant COO.

In this manner, in the electronic device 100F according to the fifth example embodiment of the present invention, the opening part 31 and the heating element 20 are connected and thereby the coolant COO is sealed. Accordingly, the heating element 20 can contact directly with the coolant COO in the case 30. Thus, the heat of the heating element 20 can be transferred efficiently to the coolant COO in the case 30, thereby accelerating the phase change of the coolant COO more efficiently. Consequently, the electronic device 100F according to the fifth example embodiment of the present invention is able to cool the heat of the heating element more efficiently.

Further, a distance between the case 30 and the heating element 20 can be increased by providing the connection unit 40. It is also possible to increase a volume for housing the coolant COO by providing the connection unit 40. Further, a size of the opening part 31 can be larger than a size of the first heating element outer surface 21 of the heating element 20. Furthermore, by interposing the connection unit 40 between the case 30 and the heating element 20, it is possible to absorb dimensional variations that occur during manufacturing of the case 30 and the heating element 20, and deformation of the heating element 20 during generating heat.

The thickness of the connection unit 40 is equal to or less than 0.21 mm. Thus, the connection unit 40 can be formed into foil by a main metal material such as aluminum, aluminum alloy, and copper. Consequently, the connection unit 40 can be more flexible, and the opening part 31 can be easily connected to the first heating element outer surface 21 of the heating element 20.

The whole or part of the example embodiments disclosed above can be described as, but not limited to, the following supplementary notes.

### (Supplementary Note 1)

An electronic device including:

a circuit board with a heating element mounted on a main surface,

a case that is provided with an opening part being formed on a surface facing the heating element and houses a coolant, and

a connection unit that connects the opening part and the heating element, thereby sealing the coolant, wherein

a thickness of the connection unit is equal to or less than 0.21 mm.

### (Supplementary Note 2)

The electronic device according to supplementary note 1, wherein the connection unit is formed of a heat conductive member.

### (Supplementary Note 3)

The electronic device according to supplementary note 1 or 2, wherein

the coolant can turn to a liquid-phase coolant and a gas-phase coolant by a phase change.

### (Supplementary Note 4)

The electronic device according to supplementary note 3 further including

a boiling acceleration unit that is provided on a first heating element outer surface being a surface on a side opposite to a surface on a side of the circuit board among outer surfaces of the heating element, and accelerates a phase change of the liquid-phase coolant around the first heating element outer surface to the gas-phase coolant by heat of the heating element.

### (Supplementary Note 5)

The electronic device according to supplementary note 4, wherein

the boiling acceleration unit is formed of a groove or a porous body formed on the first heating element outer surface.

### (Supplementary Note 6)

The electronic device according to supplementary note 4, wherein

the connection unit and the boiling acceleration unit are formed integrally.

### (Supplementary Note 7)

The electronic device according to supplementary note 6, wherein

the boiling acceleration unit is configured of a plurality of holes formed in a center part of a metal plate, and

the connection unit is configured of an outer peripheral part that surrounds the center part of the metal plate.

### (Supplementary Note 8)

The electronic device according to any one of supplementary notes 3 to 7 further including

a coolant flow path that is provided on an inner surface of the case from a side of the opening part to a surface upper than a liquid surface of the liquid-phase coolant in a vertical direction, and on a surface that faces the inner side of the case among surfaces of the connection unit, and is formed in such a way that the liquid-phase coolant flows toward the heating element.

### (Supplementary Note 9)

The electronic device according to supplementary note 8, wherein

the coolant flow path is configured in such a way that a reticulated sheet is mounted on the inner surface of the case and on the surface that faces the inner side of the case among the surfaces of the connection unit.

### (Supplementary Note 10)

The electronic device according to supplementary note 8 or 9, wherein

the coolant flow path leads the liquid-phase coolant to the heating element by a capillary phenomenon.

### (Supplementary Note 11)

The electronic device according to supplementary note 8, wherein

the boiling acceleration unit and the coolant flow path are formed integrally.

### (Supplementary Note 12)

The electronic device according to supplementary note 11, wherein

the boiling acceleration unit and the coolant flow path are configured in such a way that a reticulated sheet is mounted on the inner surface of the case from the side of the opening part to the surface upper than the liquid surface of the liquid-phase coolant in the vertical direction, on the surface that faces the inner side of the case among the surfaces of the connection unit, and on the first heating element outer surface.

### (Supplementary Note 13)

The electronic device according to any one of supplementary notes 1 to 12 further including

a holding unit that is mounted on the main surface of the circuit board, and holds the case along the opening part.

### (Supplementary Note 14)

The electronic device according to any one of supplementary notes 1 to 13 further including

a connector portion that is provided on the circuit board, and is connected with another electronic component, wherein

the case is mounted on the main surface in such a way as not to cover the connector portion.

### (Supplementary Note 15)

An electronic apparatus including

the electronic device according to supplementary note 14, and

a housing rack that includes a housing-rack-side connector portion to be connected to the connector portion, and on which the electronic device is mounted.

While the invention has been particularly shown and described with reference to exemplary embodiments thereof, the invention is not limited to these embodiments. It will be understood by those of ordinary skill in the art that various changes in form and details may be made therein without departing from the spirit and scope of the present invention as defined by the claims.

This application is based upon and claims the benefit of priority from Japanese patent application No. 2019-062948, filed on Mar. 28, 2019, the disclosure of which is incorporated herein in its entirety by reference.

### REFERENCE SIGNS LIST

10 Circuit board
11 First main surface
12 Second main surface
13 Connector portion
20 Heating element
21 First heating element outer surface
30 Case
31 Opening part
40 Connection unit
50 Holding unit
60 Boiling acceleration unit
70 Coolant flow path
100, 100A, 100B, 100C, 100D, 100E Electronic device
110 Front surface cover
200 Housing rack
210 Case
220 Circuit board
223 Housing-rack-side connector portion
500 Metal plate
600 Reticulated sheet
700 Laminated plate
701 Reticulated sheet
702 Metal sheet
1000 Electronic apparatus

What is claimed is:

1. An electronic device comprising:
a circuit board with a heating element mounted on a main surface,
a case configured to provide with an opening part being formed on a surface facing the heating element and houses a coolant, and
a connector configured to the opening part and the heating element, thereby sealing the coolant, wherein
a thickness of the connector is equal to or less than 0.21 mm.

2. The electronic device according to claim 1, wherein
the connector is formed of a heat conductive member.

3. The electronic device according to claim 1, wherein
the coolant can turn to a liquid-phase coolant and a gas-phase coolant by a phase change.

4. The electronic device according to claim 3 further comprising
a boiling accelerator configured to provide on a first heating element outer surface being a surface on a side opposite to a surface on a side of the circuit board among outer surfaces of the heating element, and accelerate a phase change of the liquid-phase coolant around the first heating element outer surface to the gas-phase coolant by heat of the heating element.

5. The electronic device according to claim 4, wherein
the boiling accelerator is formed of a groove or a porous body formed on the first heating element outer surface.

6. The electronic device according to claim 4, wherein
the connector and the boiling accelerator are formed integrally.

7. The electronic device according to claim 6, wherein
the boiling accelerator is configured of a plurality of holes formed in a center part of a metal plate, and
the connector is configured of an outer peripheral part that surrounds the center part of the metal plate.

8. The electronic device according to claim 3 further comprising
a coolant flow path configured to provide on an inner surface of the case from a side of the opening part to a surface upper than a liquid surface of the liquid-phase coolant in a vertical direction, and on a surface that faces the inner side of the case among surfaces of the connector, and form in such a way that the liquid-phase coolant flows toward the heating element.

9. The electronic device according to claim 8, wherein
the coolant flow path is configured in such a way that a reticulated sheet is mounted on the inner surface of the case and on the surface that faces the inner side of the case among the surfaces of the connector.

10. The electronic device according to claim 8, wherein
the coolant flow path leads the liquid-phase coolant to the heating element by a capillary phenomenon.

11. The electronic device according to claim 8, wherein
the boiling accelerator and the coolant flow path are formed integrally.

12. The electronic device according to claim 11, wherein
the boiling accelerator and the coolant flow path are configured in such a way that a reticulated sheet is mounted on the inner surface of the case from the side of the opening part to the surface upper than the liquid surface of the liquid-phase coolant in the vertical direction, on the surface that faces the inner side of the case among the surfaces of the connector, and on the first heating element outer surface.

13. The electronic device according to claim 1 further comprising
a holder configured to mount on the main surface of the circuit board, and hold the case along the opening part.

14. The electronic device according to claim 1 further comprising
a connector configured to provide on the circuit board, and connect with another electronic component, wherein
the case is mounted on the main surface in such a way as not to cover the connector portion.

15. An electronic apparatus comprising
the electronic device according to claim 14, and
a housing rack configured to include a housing-rack-side connector portion to be connected to the connector portion, and on which the electronic device is mounted.
